(19) United States
(12) Patent Application Publication
(10) Pub. No.: US 2025/0329365 A1
(43) Pub. Date: Oct. 23, 2025

(54) MEMORY DEVICE WHICH HAS OPTIMAL REFERENCE RESISTANCE VALUE ACCORDING TO I/O UNIT

(71) Applicant: Samsung Electronics Co., Ltd., Suwon-si (KR)

(72) Inventors: DAESHIK KIM, Suwon-si (KR); Gyuseong KANG, Suwon-si (KR); HYUN-JIN SHIN, Suwon-si (KR)

(21) Appl. No.: 19/037,138

(22) Filed: Jan. 25, 2025

(30) Foreign Application Priority Data
Apr. 17, 2024 (KR) 10-2024-0051685

(51) Int. Cl. G11C 11/16; G11C 17/02

(52) U.S. Cl. CPC G11C 11/1673; G11C 11/1655; G11C 11/1675; G11C 17/02

(57) ABSTRACT

A memory device includes a memory cell array that includes a first input/output unit and a second input/output unit, each of the first input/output unit and the second input/output unit including a first region including a plurality of memory cells and a second region including dummy memory cells, a first sensing circuit that determines data stored in the memory cells of the first input/output unit based on a first reference resistance, a second sensing circuit that determines data stored in the memory cells of the second input/output unit based on a second reference resistance, and a control logic circuit that controls a value of the first reference resistance and a value of the second reference resistance. The value of the first reference resistance and the value of the second reference resistance are different from each other.

### CROSS-REFERENCE TO RELATED APPLICATION(S)

This application claims priority under 35 U.S.C. § 119 to Korean Patent Application No. 10-2024-0051685 filed on Apr. 17, 2024, in the Korean Intellectual Property Office, the disclosure of which is incorporated by reference herein in its entirety.

### BACKGROUND

Embodiments of the present disclosure described herein relate to a semiconductor device, and more particularly, relate to a method for determining an optimal reference resistance value of a memory device including a magnetic tunnel junction element and a device including an optimal reference resistance.

Nowadays, various types of electronic devices are being used. As a high-speed and low-power electronic device is required, the demands on reliability, high speed, and low power consumption of a memory device included in the electronic device may also increase. To satisfy the demands, a magnetic memory element has been suggested as a memory element of the memory device. Because the magnetic memory element operates at high speed and provides a nonvolatile characteristic, the magnetic memory element is on the spotlight as a next-generation semiconductor memory element.

In general, the magnetic memory element may include a magnetic tunnel junction (MTJ) element. The MTJ element may include two magnetic materials and an insulating layer interposed therebetween. A resistance value of the MTJ element may vary depending on magnetization directions of the two magnetic materials. For example, the MTJ element may have a great resistance value when the magnetization directions of the two magnetic materials are anti-parallel to each other and may have a small resistance value when the magnetization directions of the two magnetic materials are parallel to each other. Data may be written or read by using a difference between the resistance values.

A reference resistance for reading data stored in the memory cell, that is, for distinguishing the parallel state and the anti-parallel state is used, and the read success or failure depends on a value of reference resistance. Optimal reference resistance values of memory chips may be different from each other due to sizes and characteristics of the MTJ element, a process deviation, etc. In addition, optimal reference resistance values may be different depending on local locations in one memory chip. Accordingly, it is very important to obtain an optimal reference resistance value for securing the reliability of the read operation.

### SUMMARY

Embodiments of the present disclosure provide a method of determining an optimal reference resistance value for determining a program state of a memory cell through the minimum number of times and a memory device including a reference resistance determined according to the method.

According to an embodiment, a memory device may include a memory cell array that includes a first input/output unit and a second input/output unit, each of the first input/output unit and the second input/output unit including a first region including a plurality of memory cells and a second region including dummy memory cells, a first sensing circuit that determines data stored in the memory cells of the first input/output unit based on a first reference resistance, a second sensing circuit that determines data stored in the memory cells of the second input/output unit based on a second reference resistance, and a control logic circuit that controls a value of the first reference resistance and a value of the second reference resistance. The value of the first reference resistance and the value of the second reference resistance may be different from each other.

According to an embodiment, a method of operating a memory device which includes a memory cell array including a plurality of input/output units and a plurality of memory cells may include programming the plurality of memory cells of the memory cell array to a first state, first counting fail bits of the memory cells programmed to the first state by using a plurality of resistances having different values from each other and outputting first counting results based on the first counting of fail bits, programming the plurality of memory cells of the memory cell array to a second state, second counting fail bits of the memory cells programmed to the second state by using the plurality of resistances and outputting second counting results based on the second counting of fail bits, selecting a value of a global reference resistance among the plurality of resistances, based on the first counting results and the second counting results, programming memory cells of a first input/output unit among the plurality of input/output units to the first state, third counting fail bits of the memory cells of the first input/output unit programmed to the first state by using a first set of resistances among the plurality of resistances and outputting third counting results based on the third counting of fail bits, programming the memory cells of the first input/output unit to the second state, fourth counting fail bits of the memory cells of the first input/output unit programmed to the second state by using the first set of resistances and outputting fourth counting results based on the fourth counting of fail bits, and selecting a value of a local reference resistance among the first set of resistances, based on the third counting results and the fourth counting results.

According to an embodiment, a memory device may include a memory cell array that includes a plurality of first cell strings, a plurality of second cell strings, a first dummy cell string, and a second dummy cell string, a first sense amplifier that includes a first input terminal to which first ends of the plurality of first cell strings are connected and a second input terminal to which a first end of the first dummy cell string is connected through a first reference resistance, a second sense amplifier that includes a first input terminal to which first ends of the plurality of second cell strings are connected and a second input terminal to which a first end of the second dummy cell string is connected through a second reference resistance, a first current source circuit that provides a first input current to the first sense amplifier, and a second current source circuit that provides a second input current to the second sense amplifier. A value of the first reference resistance and a value of the second reference resistance may be different from each other.

### BRIEF DESCRIPTION OF THE FIGURES

The above and other objects and features of the present disclosure will become apparent by describing in detail embodiments thereof with reference to the accompanying drawings.

FIG. 1 illustrates a substrate where memory chips according to an embodiment of the present disclosure are integrated.

FIG. 2 illustrates a configuration of a memory device associated with a memory chip of FIG. 1 according to example embodiments.

FIG. 3 is a circuit diagram illustrating a configuration of a memory cell array of FIG. 2 according to example embodiments.

FIG. 4 is a circuit diagram illustrating a configuration of a memory cell array of FIG. 2 according to example embodiments.

FIGS. 5 and 6 are diagrams illustrating a configuration of a memory cell of FIG. 3.

FIG. 7 is a diagram illustrating a configuration associated with a memory cell of FIG. 3.

FIG. 8 is a diagram illustrating a configuration of a memory device according to an embodiment of the present disclosure.

FIG. 9 illustrates a configuration associated with pre-program for a memory cell array of FIG. 8 according to example embodiments.

FIG. 10 illustrates a graph associated with a program state of a memory cell of FIG. 8 according to example embodiments.

FIG. 11 illustrates a configuration associated with a read operation on a memory cell array of FIG. 8 according to example embodiments.

FIG. 12 is a graph for showing how to determine a value of a global reference resistance for distinguishing program states of memory cells according to example embodiments.

FIG. 13 is a graph for showing how to determine a value of a local reference resistance for distinguishing program states of memory cells according to example embodiments.

FIG. 14 is a graph conceptually illustrating how a read margin increases when a local reference resistance value is obtained for each input/output unit, according to an embodiment of the present disclosure.

FIG. 15 conceptually illustrates a relationship between a value of a reference resistance and a value of a read voltage or a write voltage corresponding thereto according to example embodiments.

FIG. 16 illustrates a configuration associated with a read operation on a memory cell array of FIG. 8 according to example embodiments.

FIG. 17 illustrates a configuration of a reference resistance of FIG. 11 according to example embodiments.

FIGS. 18 and 19 are circuit diagrams associated with a program operation of a write driver of FIG. 9 according to example embodiments.

FIG. 20 is a flowchart illustrating a test method of a memory device according to an embodiment of the present disclosure.

FIG. 21 is a flowchart illustrating a test method of a memory device according to an embodiment of the present disclosure.

FIG. 22 is a flowchart illustrating a test method of a memory device according to an embodiment of the present disclosure.

FIG. 23 is a block diagram associated with testing a memory device, according to an embodiment of the present disclosure.

FIG. 24 is a diagram illustrating a system to which a memory device according to an embodiment of the present disclosure is applied.

### DETAILED DESCRIPTION

Below, various example embodiments of the present disclosure will be described in detail and clearly to such an extent that an ordinary one in the art easily carries out the present disclosure.

In the detailed description, components which are described with reference to the terms “unit”, “module”, “block”, “˜er or ˜or”, etc. and function blocks which are illustrated in drawings will be implemented in the form of software or hardware or a combination thereof. For example, the software may include a machine code, firmware, an embedded code, and application software. For example, the hardware may include an electrical circuit, an electronic circuit, a processor, a computer, an integrated circuit, integrated circuit cores, a pressure sensor, an inertial sensor, a microelectromechanical system (MEMS), a passive element, or a combination thereof.

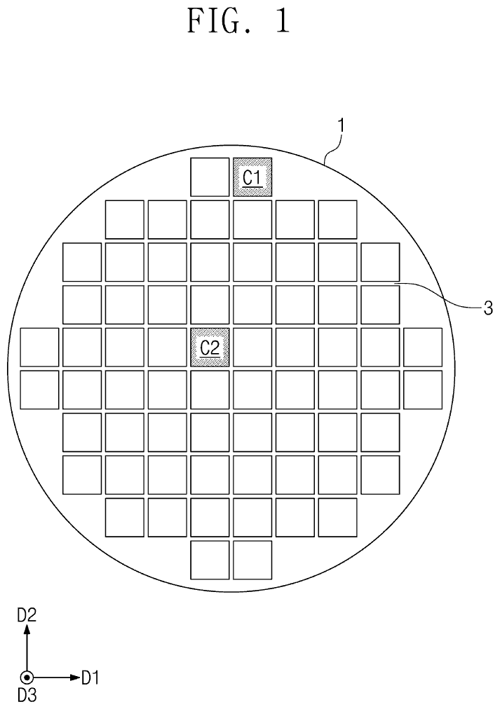

FIG. 1 illustrates a substrate 1 where memory chips are integrated, according to an embodiment of the present disclosure. The substrate 1 may include a plurality of memory chips including a first memory chip C1 and a second memory chip C2, and a scribe line region 3 between the memory chips. The memory chips may be two-dimensionally arranged along a first direction D1 and a second direction D2. Each chip may be surrounded by the scribe line region 3. That is, the scribe line region 3 may be defined between memory chips adjacent in the first direction D1 and between memory chips adjacent in the second direction D2.

In an embodiment, the substrate 1 may be a semiconductor substrate such as a semiconductor wafer. The substrate 1 may be a bulk silicon substrate, a silicon on insulator (SOI) substrate, a germanium substrate, a germanium on insulator (GOI) substrate, a silicon-germanium substrate, or a substrate of an epitaxial thin film formed through selective epitaxial growth (SEG). For example, the substrate 1 may include at least one of silicon (Si), germanium (Ge), silicon germanium (SiGe), gallium arsenic (GaAs), indium gallium arsenide (InGaAs), aluminum gallium arsenide (AlGaAs), or a mixture thereof. The substrate 1 may have a single crystalline structure.

For example, the first memory chip C1 may represent a memory chip formed relatively at a periphery of the substrate 1, and the second memory chip C2 may represents a memory chip formed relatively on the center of the substrate 1.

Meanwhile, a program characteristic and a reference resistance characteristic of memory cells constituting a memory chip may vary depending on a location on the substrate 1, at which the memory chip is formed. For example, when the memory chips formed on the substrate 1 include MRAM cells, the size of the MRAM cell may vary depending on a location in the substrate 1, at which a memory device is formed.

For example, the size of the MRAM cell of the first memory chip C1 placed on an outer side of the substrate 1 may be relatively small due to the manufacturing process. In contrast, the size of the MRAM cell of the second memory chip C2 placed on an inner side of the substrate 1 may be relatively large due to the manufacturing process. In contrast, due to the manufacturing process, the size of the MRAM cell of the first memory chip C1 may be relatively large, and the size of the MRAM cell of the second memory chip C2 may be relatively small.

In general, an MTJ resistance of an MRAM cell with a relatively large size may be smaller in value than an MTJ resistance of an MRAM cell with a relatively small size. A value of a reference resistance for determining a program state of an MRAM cell interworks with a value of the MTJ resistance. In other words, as the value of the MTJ resistance of the MRAM cell becomes greater, the value of the reference resistance becomes greater; as the value of the MTJ resistance of the MRAM cell becomes smaller, the value of the reference resistance becomes smaller. According to an embodiment of the present disclosure, an optimal global reference resistance value for the read operation or the write operation of a relevant chip is determined in consideration of a relative size of the MRAM cell.

In addition, sizes of the MRAM cells may be different depending on locations of memory cells in one memory chip. Accordingly, in the case of applying the same optimal global reference resistance value to the read operations of the memory device, even though the read operation is well performed in association with a specific input/output unit, the read operation on a specific input/output unit may be failed. A definition of the input/output unit and a configuration of a memory device preventing the failure of the read operation on the specific input/output unit will be described in detail later.

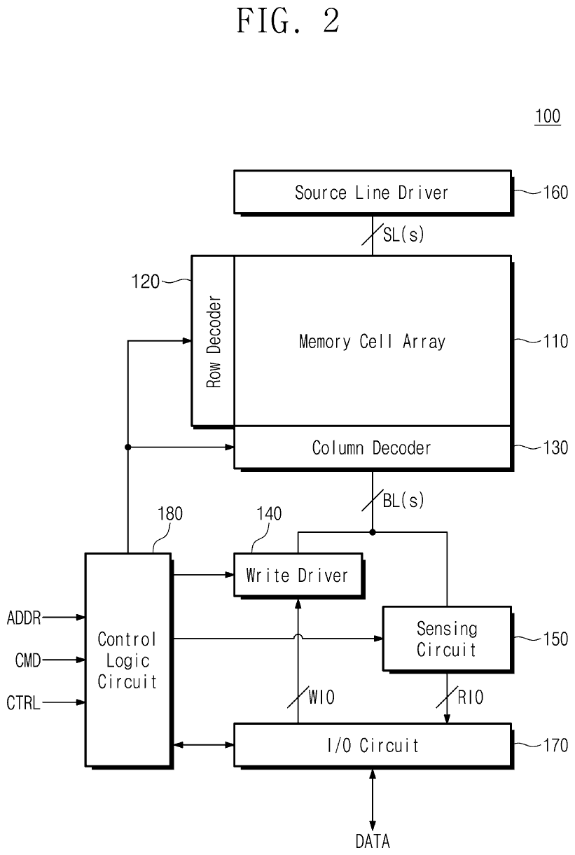

FIG. 2 illustrates a configuration of a memory device associated with the memory chips C1 and C2 of FIG. 1 according to example embodiments.

A memory device 100 may include a memory cell array 110, a row decoder 120, a column decoder 130, a write driver 140, a sensing circuit 150, a source line driver 160, an input/output circuit 170, and a control logic circuit 180. In an embodiment, each of the memory chips C1 and C2 of FIG. 1 may include the memory cell array 110. However, the present invention is not limited thereto. For example, each of the memory chips C1 and C2 may further include one or more of the remaining components of the memory device 100, in addition to the memory cell array 110.

The memory cell array 110 may include a plurality of memory cells each configured to store data. For example, each memory cell may include a variable resistance element, and a value of data stored therein may be determined based on a resistance value of the variable resistance element. For example, each memory cell may include a magneto-resistive RAM (MRAM) cell, a spin transfer torque MRAM (STT-MRAM) cell, a spin-orbit torque MRAM (SOT-MRAM) cell, a phase-change RAM (PRAM) cell, a resistive RAM (ReRAM) cell, etc. In the specification, below, the description will be given under the assumption that each memory cell includes an STT-MRAM cell.

The memory cells constituting the memory cell array 110 may be connected to source lines SL, bit lines BL, and word lines. For example, memory cells arranged along a row may be connected in common to a word line corresponding to the row, and memory cells arranged along a column may be connected in common to a source line and a bit line corresponding to the column.

The row decoder 120 may select (or drive) a word line connected to a memory cell targeted for the read operation or the program operation under control of the control logic circuit 180. The row decoder 120 may provide the selected word line with a driving voltage provided from the control logic circuit 180.

The column decoder 130 may select the bit line BL and/or the source line SL connected to the memory cell targeted for the read operation or the program operation under control of the control logic circuit 180.

In the program operation, the write driver 140 may drive a program voltage (or a write current) for storing write data in a memory cell selected by the row decoder 120 and the column decoder 130. For example, in the program operation of the memory device 100, the write driver 140 may store the write data in the selected memory cell by controlling a voltage of a data line DL based on the write data provided from the input/output circuit 170 through a write input/output line WIO.

In the read operation, the sensing circuit 150 may sense a signal output through the bit line BL and may determine a value of data stored in the selected memory cell. The sensing circuit 150 may be connected to the column decoder 130 through the bit line BL and may be connected to the input/output circuit 170 through a read input/output line RIO. The sensing circuit 150 may output the sensed read data to the input/output circuit 170 through the read input/output line RIO.

The source line driver 160 may drive the source line SL to a target voltage level under control of the control logic circuit 180. For example, the source line driver 160 may be provided with a voltage for driving the source line SL from the control logic circuit 180. For example, a value of a voltage applied from the source line driver 160 to the source line SL when the program operation is performed such that a memory cell has a great resistance value (e.g., an anti-parallel state) may be different from a value of a voltage applied from the source line driver 160 to the source line SL when the program operation is performed such that a memory cell has a small resistance value (e.g., a parallel state).

In the program operation, the input/output circuit 170 may receive write data “DATA” from the outside and may provide the received write data to the write driver 140. In the read operation, the input/output circuit 170 may read data from the memory cell array 110 and may output the read data to the outside as read data “DATA”.

The control logic circuit 180 may receive a command CMD, an address ADDR, and a control signal CTRL from the outside. The control logic circuit 180 may control the components of the memory device 100, based on the command CMD, the address ADDR, and the control signal CTRL. For example, the control logic circuit 180 may control the row decoder 120 and the column decoder 130, and thus, a target memory cell on which the program operation or the read operation is to be performed may be selected.

In an embodiment, the control logic circuit 180 may control a value of the reference resistance, which is used to determine a program state of a memory cell, based on the control signal CTRL. In this case, the control signal CTRL may include information about an optimal value of the reference resistance which is used to determine a program state of a memory cell.

Meanwhile, although not illustrated in drawing, the memory device 100 may further include a one-time programmable (OTP) memory. Information about the memory device 100 may be programmed in the OTP memory. In an embodiment, information about a fail address of the memory cell array 110, information about internal voltages (e.g., a program voltage and a read voltage) of the memory device 100, etc. may be programmed in the OTP memory. In particular, according to an embodiment of the present disclosure, an optimal reference resistance value, a program voltage (current) value, a read voltage (current) value, etc. which are determined in the process of testing a memory device may be programmed in the OTP memory.

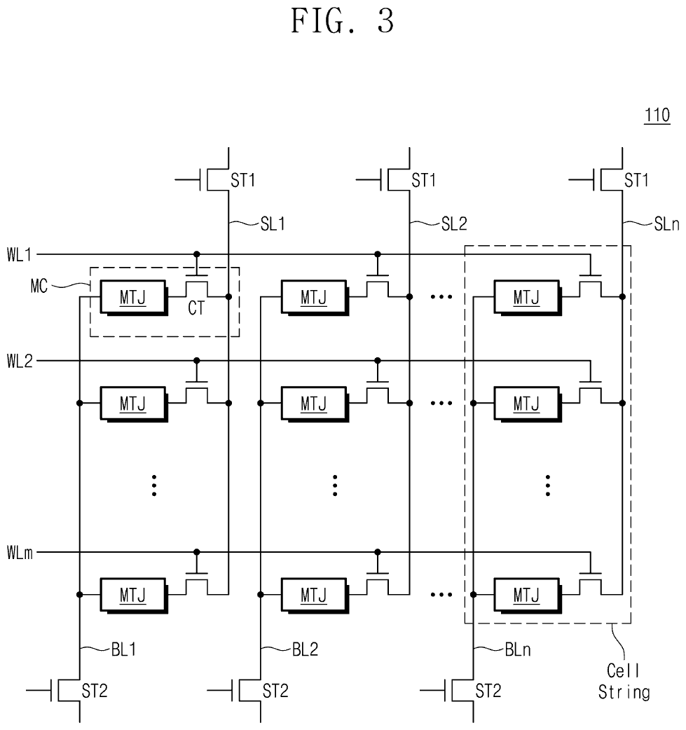

FIG. 3 is a circuit diagram illustrating a configuration of the memory cell array 110 of FIG. 2 according to example embodiments.

Select transistors ST1 and ST2 among components illustrated in FIG. 3 may constitute the column decoder 130 (refer to FIG. 2) and are illustrated together with the memory cell array 110 to represent the connection relationship with the memory cell array 110.

The memory cell array 110 may include a plurality of memory cells arranged along row and column directions. A memory cell MC may include a magnetic tunnel junction (MTJ) element and a cell transistor CT. As the MTJ element of the memory cell MC is programmed to have a specific resistance value, data corresponding to the specific resistance value may be stored in the memory cell MC. A cell string may include a plurality of memory cells which are connected in common to one bit line and one source line.

The plurality of memory cells may be connected to word lines WL1 to WLm, bit lines BL1 to BLn, and source lines SL1 to SLn, each of m and n being a natural number equal to or greater than 2. A first end of the MTJ element may be connected to the first bit line BL1, and a second end of the MTJ element may be connected to a first end of the cell transistor CT. A second end of the cell transistor CT may be connected to the first source line SL1, and a gate electrode of the cell transistor CT may be connected to the first word line WL1. The source lines SL1 to SLn may be respectively connected to the select transistors ST1, and the bit lines BL1 to BLn may be respectively connected to the select transistors ST2.

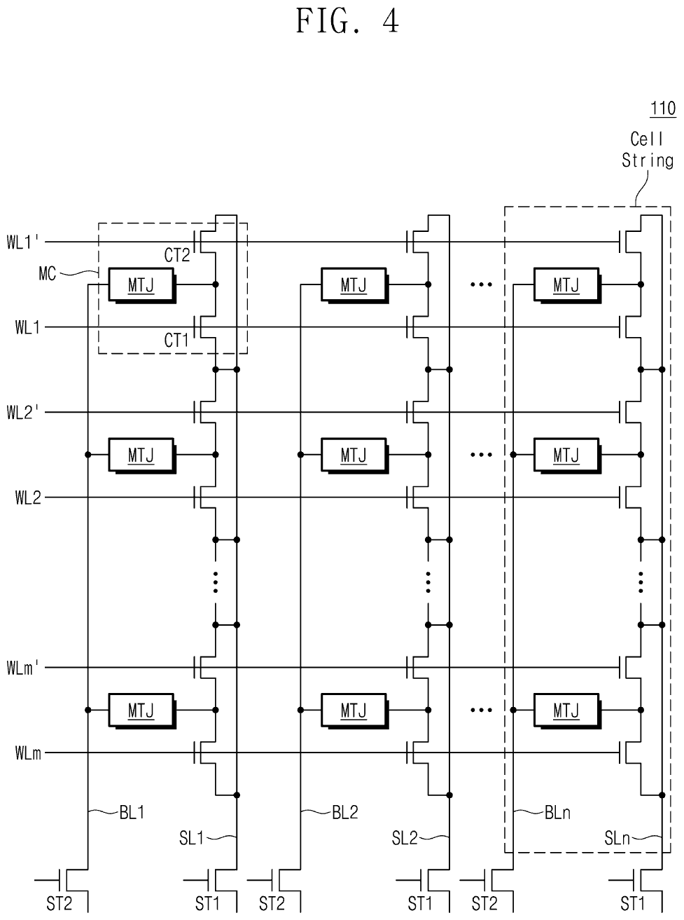

FIG. 4 is a circuit diagram illustrating a configuration of the memory cell array 110 of FIG. 2 according to example embodiments.

The select transistors ST1 and ST2 among components illustrated in FIG. 4 may constitute the column decoder 130 (refer to FIG. 2) and are illustrated together with the memory cell array 110 to represent the connection relationship with the memory cell array 110.

The memory cell array 110 may include a plurality of memory cells arranged along row and column directions. A memory cell MC may include a magnetic tunnel junction (MTJ) element and two cell transistors CT1 and CT2. A cell string may include a plurality of memory cells which are connected in common to one bit line and one source line.

The memory cell MC may have a structure in which two cell transistors CT1 and CT2 share one MTJ element. A first end of the MTJ element may be connected to the first bit line BL1, and a second end of the MTJ element may be connected to first ends of the cell transistors CT1 and CT2. Second ends of the cell transistors CT1 and CT2 may be connected to the first source line SL1. A gate electrode of the first cell transistor CT1 may be connected to the first word line WL1, and a gate electrode of the second cell transistor CT2 may be connected to a first sub-word line WL1′. Each of the cell transistors CT1 and CT2 may be turned on or turned off by a signal (or a voltage) provided through a word line or a sub-word line.

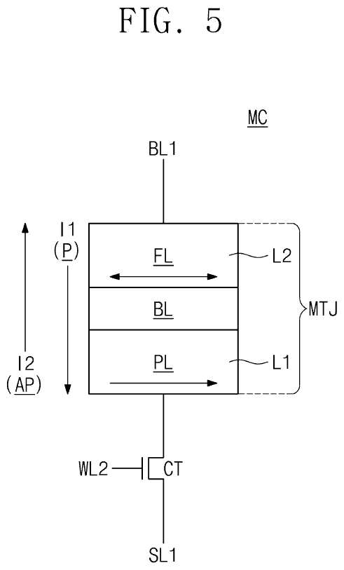

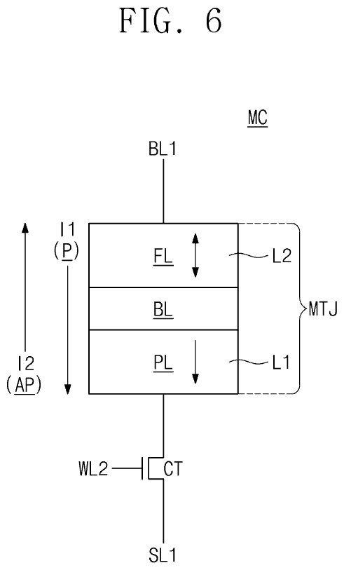

FIGS. 5 and 6 illustrate a configuration of a memory cell of FIG. 3.

Referring to FIGS. 5 and 6, an MTJ element may include a first magnetic layer L1, a second magnetic layer L2, and a barrier layer BL (or a tunneling layer) interposed between the first magnetic layer L1 and the second magnetic layer L2. The barrier layer BL may include at least one of a magnesium (Mg) oxide layer, a titanium (Ti) oxide layer, an aluminum (Al) oxide layer, a magnesium-zinc (Mg—Zn) oxide layer, or a magnesium-boron (Mg—B) oxide layer, or a combination thereof. Each of the first magnetic layer Ll and the second magnetic layer L2 may include at least one magnetic layer.

In detail, the first magnetic layer L1 may include a reference layer (e.g., a pinned layer PL) having a magnetization direction fixed (or pinned) in a specific direction, and the second magnetic layer L2 may include a free layer FL having a magnetization direction changeable to be parallel or anti-parallel to the magnetization direction of the reference layer. However, FIGS. 5 and 6 show, for example, the case where the first magnetic layer L1 includes the reference layer PL and the second magnetic layer L2 includes the free layer FL, but the present invention is not limited thereto. For example, unlike the example illustrated in FIGS. 5 and 6, the first magnetic layer L1 may include a free layer, and the second magnetic layer L2 may include a pinned layer.

In an embodiment, as illustrated in FIG. 5, magnetization directions may be mostly parallel to an interface of the barrier layer BL and the first magnetic layer L1. In this case, each of the reference layer and the free layer may include a ferromagnetic material. For example, the reference layer may further include an anti-ferromagnetic material for pinning a magnetization direction of the ferromagnetic material.

In an embodiment, as illustrated in FIG. 6, magnetization directions may be mostly perpendicular to the interface of the barrier layer BL and the first magnetic layer L1. In this case, each of the reference layer and the free layer may include at least one of a perpendicular magnetic material (e.g., CoFeTb, CoFeGd, or CoFeDy), a perpendicular magnetic material with an L10 structure, a CoPt based material with a hexagonal-close-packed-lattice structure, and perpendicular magnetic structures, or a combination thereof. The perpendicular magnetic material with the L10 structure may include at least one of FePt with the L10 structure, FePd with the L10 structure, CoPd with the L10 structure, or CoPt with the L10 structure, or a combination thereof. The perpendicular magnetic structure may include magnetic layers and non-magnetic layers which are alternately and repeatedly stacked. For example, the perpendicular magnetic structure may include at least one of (Co/Pt)n, (CoFe/Pt)n, (CoFe/Pd)n, (Co/Pd)n, (Co/Ni)n, (CoNi/Pt)n, (CoCr/Pt)n, or (CoCr/Pd)n (n being the number of stacked layers), or a combination thereof. Here, the thickness of the reference layer may be greater than the thickness of the free layer, or a coercive force of the reference layer may be greater than a coercive force of the free layer.

In an embodiment, when a voltage of a relatively high level is applied to the bit line BL1 and a voltage of a relatively low level is applied to the source line SL1, a write current I1 may flow. In this case, the magnetization direction of the second magnetic layer L2 may be the same as the magnetization direction of the first magnetic layer L1, and thus, the MTJ element may have a low resistance value (i.e., a parallel state).

In contrast, when a voltage of a relatively high level is applied to the source line SL1 and a voltage of a relatively low level is applied to the bit line BL1, a write current 12 may flow. In this case, the magnetization direction of the second magnetic layer L2 may be opposite to the magnetization direction of the first magnetic layer L1, and thus, the MTJ element may have a great resistance value (i.e., an anti-parallel state).

In an embodiment, when the MTJ element is in the parallel state, the memory cell MC may be regarded as storing data of a first value (e.g., logic “0”). In contrast, when the MTJ element is in the anti-parallel state, the memory cell MC may be regarded as storing data of a second value (e.g., logic “1”).

Meanwhile, one cell transistor CT is only illustrated in FIGS. 5 and 6, but the components illustrated in FIGS. 5 and 6 may also be applied to the memory cell of FIG. 4. In this case, the cell transistors CT1 and CT2 may be connected to the first end of the MTJ element. The basic principle, operation, etc. of the MTJ element may be identically applied to the memory cell of FIG. 4 except that a current path changes depending on a cell transistor turned on from among the cell transistors CT1 and CT2.

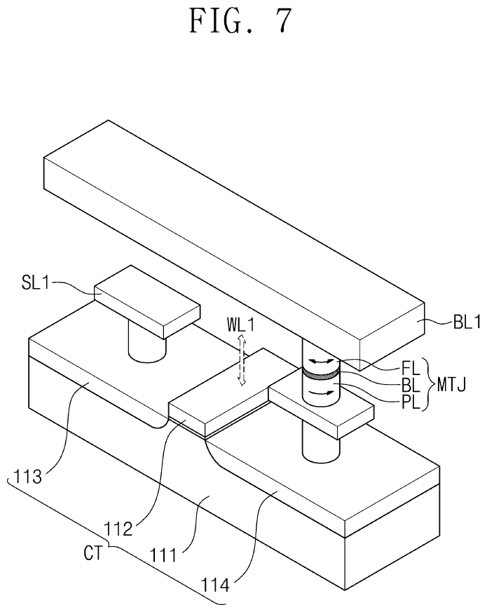

FIG. 7 is a diagram illustrating a configuration associated with a memory cell of FIG. 3.

The cell transistor CT may include a body substrate 111, a gate electrode 112, and junctions 113 and 114. The junction 113 may be formed on the body substrate 111 and may be connected to the source line SL1. The junction 114 may be formed on the body substrate 111 and may be connected to the bit line BL1 through the MTJ element. The gate electrode 112 may be formed on the body substrate 111 between the junctions 113 and 114 and may be connected to the word line WL1. Meanwhile, the configuration of FIG. 7 is provided as an example. Like the embodiment described with reference to FIG. 6, in the case where two cell transistors share one MTJ element, a modified version of the configuration illustrated in FIG. 4 may be adopted.

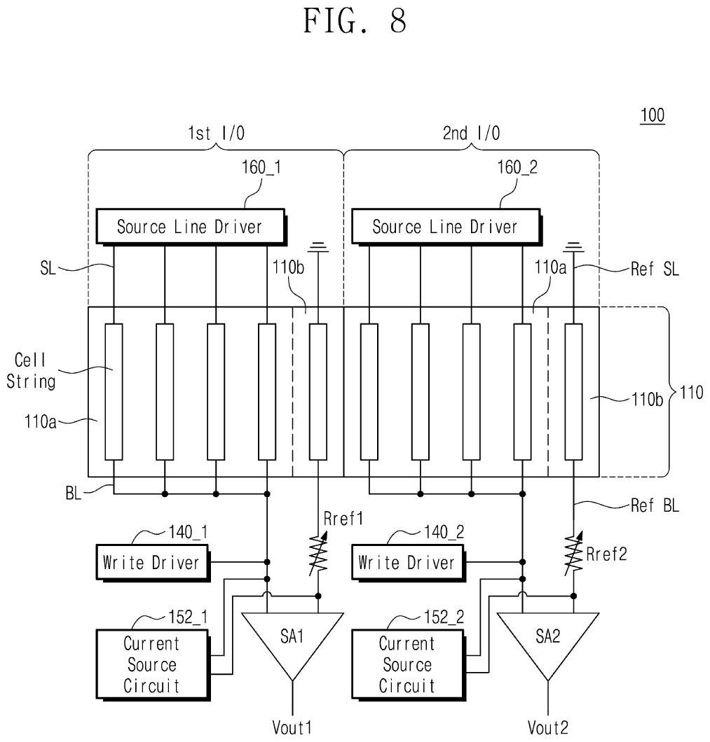

FIG. 8 illustrates a configuration of the memory device 100 according to an embodiment of the present disclosure.

The memory device 100 may be mostly similar to the memory device of FIG. 2. However, for brevity of illustration, some components for selecting a string, such as the column decoder 130 (refer to FIG. 2) and the row decoder 120 (refer to FIG. 2), are not illustrated.

The memory device 100 may include a first input/output unit 1st I/O and a second input/output unit 2nd I/O. The first input/output unit 1st I/O may include a portion of the memory cell array 110, a write driver 140_1, a current source circuit 152_1, a source line driver 160_1, and a sense amplifier SA1. The second input/output unit 2nd I/O may include a portion of the memory cell array 110, a write driver 140_2, a current source circuit 152_2, a source line driver 160_2, and a sense amplifier SA2. The portion of the memory cell array 110 of each of the input/output units 1st I/O and 2nd I/O may include a first region 110a and a second region 110b. The current source circuit 152_1 and the sense amplifier SA1 may constitute the sensing circuit 150 of FIG. 2.

An input/output unit may mean a unit by which the read operation and/or the write operation is independently performed. Accordingly, while the write operation (i.e., the program operation) on the first input/output unit 1st I/O is performed, the write operation on the second input/output unit 2nd I/O may also be performed; while the read operation on the first input/output unit 1st I/O is performed, the read operation on the second input/output unit 2nd I/O may also be performed. For example, one sense amplifier, one write driver, and one source line driver may correspond to a memory cell array included in one input/output unit.

The first region 110a of each of the input/output units 1st I/O and 2nd I/O may include a plurality of cell strings. Each cell string may include the plurality of memory cells MC (refer to FIG. 3 or 4). For example, a first end of each cell string of the first input/output unit 1st I/O may be connected to a first input terminal of each of the write driver 140_1, the current source circuit 152_1, and the sense amplifier SA1 through the bit line BL, and a second end thereof may be connected to the source line driver 160_1 through the source line SL.

The second region 110b of each of the input/output units 1st I/O and 2nd I/O may include one (or more) dummy cell string. The dummy cell string of the second region 110b may include a plurality of dummy memory cells. For example, a first end of the dummy cell string of the first input/output unit 1st I/O may be connected to a second input terminal of the sense amplifier SA1 through a reference bit line Ref BL and a reference resistance Rref1, and a second end thereof may be connected to a ground electrode (or a ground).

A configuration of the second input/output unit 2nd I/O is mostly the same as the configuration of the first input/output unit 1st I/O, and thus, additional description will be omitted to avoid redundancy. An embodiment where the memory cell array 110 is related to two input/output units is illustrated, but the present invention is not limited thereto. For example, the memory device 100 may include three or more input/output units; in this case, the number of write drivers, the number of source line drivers, and the number of sense amplifiers may be the same as the number of input/output units.

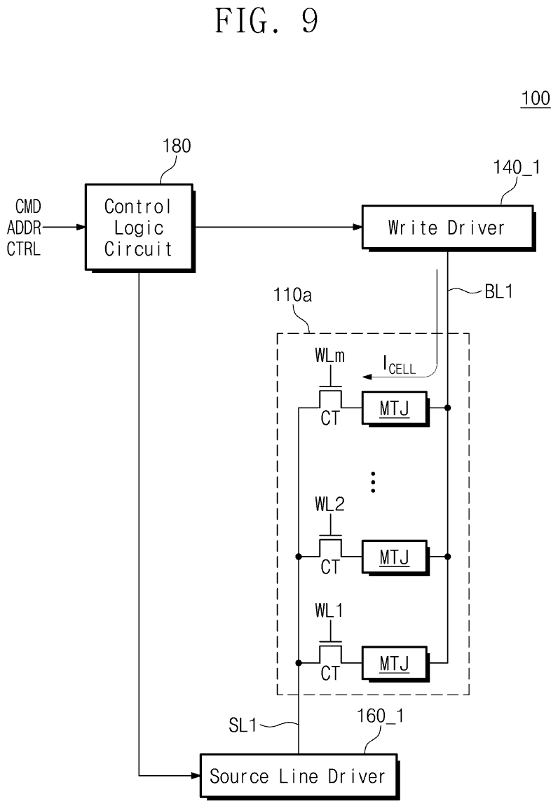

FIG. 9 illustrates a configuration associated with pre-program for the memory cell array 110 of FIG. 8 according to example embodiments

In an embodiment, a pre-program operation is not for storing data and may be associated with a program operation for searching for an optimal value of the reference resistance for distinguishing the parallel state and the anti-parallel state in the process of testing a memory device. A pre-program voltage may be a voltage whose level is sufficient to such an extent that the program operation on memory cells is not failed. Accordingly, the level of the pre-program voltage may be higher than the level of the program voltage used in a normal program operation. This may be associated with preventing the program fail to accurately perform the test operation.

A memory cell array (e.g., 110 of FIG. 8) may include a plurality of memory cells each including an MTJ element and a cell transistor. The write driver 140_1, the source line driver 160_1, and the control logic circuit 180 are illustrated together with the first region 110a of the memory cell array. The memory cells may be connected to the write driver 140_1 through the first bit line BL1 and may be connected to the source line driver 160_1 through the first source line SL1.

The control logic circuit 180 may be configured to generate a voltage for performing the pre-program operation on the first region 110a of the memory cell array. For example, the control logic circuit 180 may individually control components constituting the write driver 140_1, based on the control signal CTRL.

The write driver 140_1 may perform the pre-program operation on memory cells under control of the control logic circuit 180. The pre-program operation may include programming the memory cells to have the parallel state and programming the memory cells to have the anti-parallel state. The write driver 140_1 may output a write current ICELL (or a write voltage) corresponding to the parallel state or the anti-parallel state. For example, the write driver 140_1 may include a driver circuit configured to generate the write current ICELL to perform the pre-program operation on the memory cells.

In an embodiment, a global reference resistance to be globally applied to the memory device 100 and a local reference resistance to be locally applied only to an input/output unit may be obtained as a value of a reference resistance for determining the program state of the memory cell in the process of testing the memory device 100. For example, to obtain the global reference resistance, all the memory cells of the memory device 100 may be pre-programmed by the write driver 140 (refer to FIG. 2). To obtain the local reference resistance, the memory cells may be pre-programmed in units of input/output unit (e.g., by the write driver 140_1).

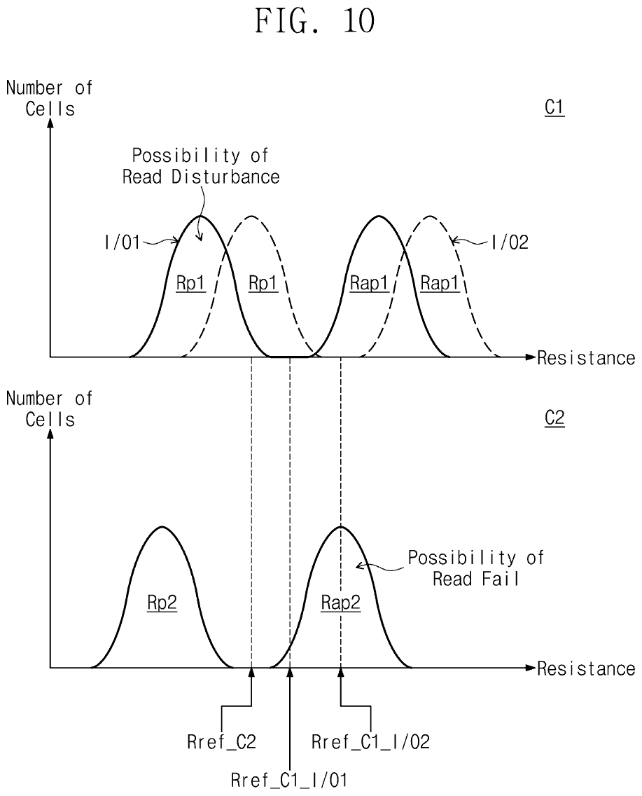

FIG. 10 illustrates resistance distributions of pre-programmed (or programmed) memory cells according to example embodiments.

Like the brief description given with reference to FIG. 1, the characteristics of the memory chips C1 and C2 manufactured from the same substrate 1 may be different from each other due to various process issues. For example, a resistance distribution diagram corresponding to the first memory chip C1 may be different from a resistance distribution diagram corresponding to the second memory chip C2. For example, when the size of the MRAM cell constituting the first memory chip C1 is smaller than the size of the MRAM cell constituting the second memory chip C2, a resistance value of the MRAM cell of the first memory chip C1 may be mostly greater than a resistance value of the MRAM cell of the second memory chip C2.

In addition, a value of a read voltage (or current) necessary to perform the read operation on the MRAM cell of the first memory chip C1 may be mostly smaller than a value of a read voltage (or current) necessary to perform the read operation on the MRAM cell of the second memory chip C2. However, in another embodiment, when the size of the MRAM cell constituting the first memory chip C1 is larger than the size of the MRAM cell constituting the second memory chip C2, the resistance characteristic and the read voltage characteristic may be opposite to those described above.

For example, memory cells of a first input/output unit of the first memory chip C1 may have a resistance distribution Rp1 illustrated by a solid line and a resistance distribution Rap1 illustrated by a solid line. The resistance distribution Rp1 illustrated by the solid line indicates a resistance distribution of memory cells programmed to the parallel state, and the resistance distribution Rap1 illustrated by the solid line indicates a resistance distribution of memory cells programmed to the anti-parallel state. The resistance distributions Rp1 and Rap1 illustrated by the solid line may be distinguished by a reference resistance Rref_C1_I/O1.

Memory cells of a second input/output unit of the first memory chip C1 may have the resistance distribution Rp1 illustrated by a dash-single dotted line and the resistance distribution Rap1 illustrated by a dash-single dotted line. The resistance distribution Rp1 illustrated by the dash-single dotted line indicates a resistance distribution of memory cells programmed to the parallel state, and the resistance distribution Rap1 illustrated by the dash-single dotted line indicates a resistance distribution of memory cells programmed to the anti-parallel state. The resistance distributions Rp1 and Rap1 illustrated by the dash-single dotted line may be distinguished by a reference resistance Rref_C1_I/O2.

Memory cells of the second memory chip C2 may have a resistance distribution Rp2 and a resistance distribution Rap2. The resistance distribution Rp2 indicates a resistance distribution of memory cells programmed to the parallel state, and the resistance distribution Rap2 indicates a resistance distribution of memory cells programmed to the anti-parallel state. The resistance distributions Rp2 and Rap2 may be distinguished by a second reference resistance Rref_C2.

However, magnitudes of read voltages corresponding to the reference resistances Rref_C1_I/O1 and Rref_C1_1/O2 may be somewhat small to determine program states of the memory cells of the second memory chip C2. The reason is that a relatively great read voltage may be required to determine the program states of the memory cells of the second memory chip C2 in which a cell size is relatively large. That is, the read fail may occur when the read operation on the memory cells of the second memory chip C2 is performed by using the voltage of the relatively small value corresponding to the reference resistance Rref_C1_I/O1 or Rref_C1_I/O2.

Magnitudes of program voltages corresponding to the reference resistance Rref_C1_I/O1 or Rref_C1_I/O2 may be somewhat small to determine the program states of the memory cells of the second memory chip C2. The reason is that a relatively great program voltage may be required to determine the program states of the memory cells of the second memory chip C2 in which a cell size is relatively large. That is, a write fail may occur when the write operation on the second memory chip C2 is performed by using a write voltage of a relatively small value corresponding to the reference resistance Rref_C1_I/O1 or Rref_C1_I/O2.

In contrast, a magnitude of a read voltage corresponding to the reference resistance Rref_C2 may be somewhat great to determine the program states of the memory cells of the first memory chip C1, and when the read operation on the first memory chip C1 is performed by using the read voltage corresponding to the reference resistance Rref_C2, the read disturbance may occur due to the change of a spin state of a memory cell. Also, when the write operation of the first memory chip C1 is performed by using a program voltage of a relatively great value, which corresponds to the reference resistance Rref_C2, an endurance issue may occur at memory cells.

As a result, an unintended issue may occur when the read operation on the memory chips C1 and C2 manufactured from the same wafer 1 (refer to FIG. 1) is performed by using the same reference resistance value. In addition, even though memory cells belong to one memory chip (e.g., C1), an optimal reference resistance for determining a program state of a memory cell may have different values for respective locations of memory cells. Accordingly, when the same reference resistance value is applied to input/output units during the read operation on the memory chip C1, there may be an input/output unit in which an issue such as a decrease in the read margin or a read fail occurs.

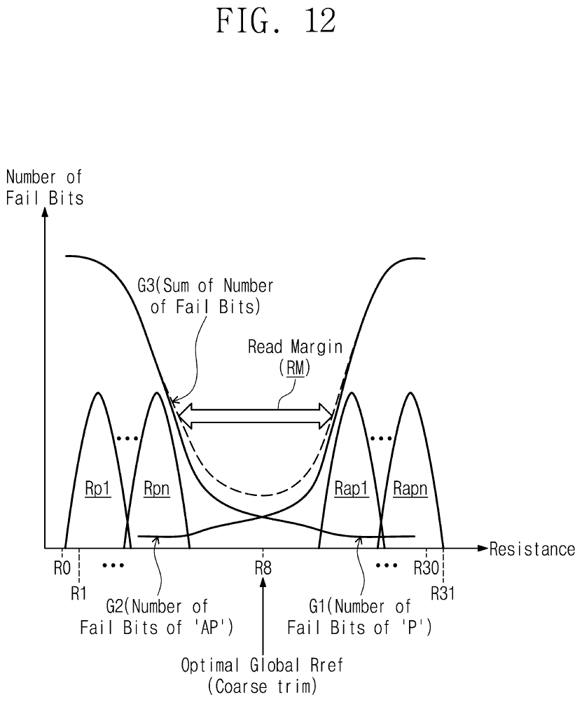

To solve the above issue, according to an embodiment of the present disclosure, an optimal global reference resistance value capable of being applied to the whole memory chip may be first determined, and an optimal local reference resistance value capable of being individually applied to each input/output unit may then be determined. A configuration and an operating method of a memory device for providing an optimal local reference resistance value will be described in detail from FIG. 12.

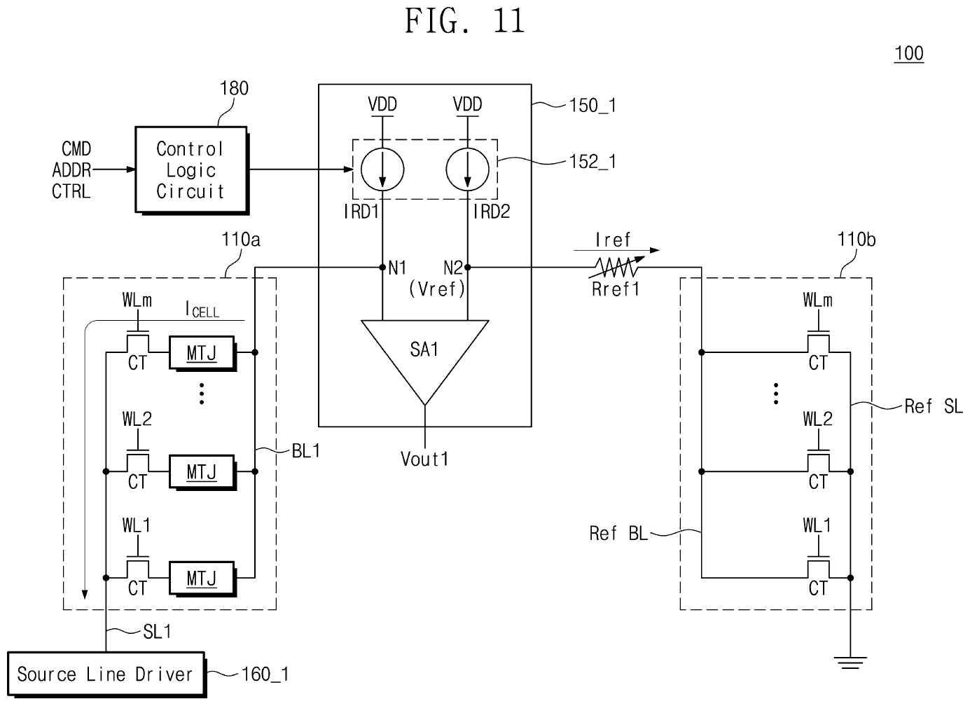

FIG. 11 illustrates a configuration associated with a read operation on the memory cell array 110 of FIG. 8 according to example embodiments.

In an embodiment, the read operation may mean an operation of reading fail bits to determine an optimal reference resistance value in the process of testing a memory device, as well as an operation of reading data stored in memory cells at an end-user level. For example, to read a fail bit and to determine an optimal reference resistance value, a value of the reference resistance Rref1 may vary under control of the control logic circuit 180.

The memory device 100 may include the memory cell array composed of the first region 110a and the second region 110b, a sensing circuit 150_1, the source line driver 160_1, and the control logic circuit 180. For brevity of illustration, one of the cell strings of the first region 110a is only illustrated.

The first region 110a may include a plurality of memory cells connected to the first bit line BL1 and the first source line SL1, and each memory cell may include an MTJ element and a cell transistor. The first bit line BL1 may be connected to a first node N1, and the first source line SL1 may be connected to the source line driver 160_1.

The second region 110b may include components which are necessary to generate a reference voltage Vref used to read data stored in a memory cell of the first region 110a. The second region 110b may include a reference bit line Ref BL, a reference source line Ref SL, and a plurality of cell transistors CT. The second region 110b may be called a dummy region in that an MTJ element is not included therein, and a memory cell of the second region 110b may be called a dummy memory cell.

The sensing circuit 150_1 may be configured to read data stored in a memory cell connected to the first bit line BL1. For example, the sensing circuit 150_1 may include the current source circuit 152_1 generating a first read current IRD1 and a second read current IRD2, and the sense amplifier SA1. For example, the first read current IRD1 may be generated from a first current source of the current source circuit 152_1 and the second read current IRD2 may be generated from a second current source of the current source circuit 152_1.

The first read current IRD1 may be used to sense a voltage drop on the first bit line BL1, which is caused depending on a state of a selected memory cell. For example, the first read current IRD1 may be input to the MTJ element of the selected memory cell which is connected to a selected word line (i.e., WLm) and the first bit line BL1. As a result, the voltage drop is made by the MTJ element connected to the m-th word line WLm.

The second read current IRD2 may be used to determine a voltage drop made by the reference resistance Rref1 connected to a second node N2 through the reference bit line Ref BL. For example, when the second read current IRD2 flows through the reference resistance Rref1, the voltage drop may be made by the reference resistance Rref1. In an embodiment, a reference current Iref is illustrated in FIG. 11 to show a current flowing through the reference resistance Rref1, but the reference current Iref may be regarded as substantially/mostly the same as the second read current IRD2.

The sense amplifier SA1 may sense a voltage difference of the first node N1 and the second node N2 and may amplify the sensed voltage difference. Depending on a program state of a memory cell, a voltage level of the first node N1 may be different from a voltage level of the second node N2. The amplified voltage difference may be output as an output voltage Vout1 and may be used to determine the data read from the memory cell.

In an embodiment, in the process of testing the memory device 100, the number of fail bits of memory cells programmed to the parallel state or the anti-parallel state may be counted for each value of the reference resistance Rref1. A value of a global reference resistance for determining program states of memory cells may be obtained through the global application to the memory device 100 based on the number of fail bits. In addition, a value of a local reference resistance to be applied to each input/output unit may be obtained based on the global reference resistance value. In an embodiment, the obtained local reference resistance value may be adopted as a value of the reference resistance Rref1.

FIG. 12 is a graph for showing how to determine a value of a global reference resistance for distinguishing program states of memory cells according to example embodiments.

Referring to FIGS. 9, 11, and 12, in the test operation of the memory device 100, the pre-program operation on the memory device 100 may be performed. For example, a test device (e.g., automatic test equipment (ATE)) may program the memory cells of the memory device 100 to the parallel state. Resistance values of the memory cells programmed to the parallel state may be distributed like Rp1 to Rpn. Herein, Rp1 may indicate a resistance distribution of memory cells of a first input/output unit, and Rpn may indicate a resistance distribution of memory cells of an n-th input/output unit, n being a natural number equal to or greater than 2.

The test device may count the number of fail bits of the memory cells of the memory device 100. For example, when the read operation is performed by using a reference resistance of a relatively small value (e.g., R1), the number of fail bits may be great. As a value (e.g., R31) of the reference resistance becomes greater, the number of fail bits may decrease. As the reference resistance value varies, the number of counted fail bits varies like a graph marked by G1.

When the fail bit counting for the memory cells programmed to the parallel state is completed, the test device may program the memory cells of the memory device 100 to the anti-parallel state. Resistance values of the memory cells programmed to the anti-parallel state may be distributed like Rap1 to Rapn. Herein, Rap1 may indicate a resistance distribution of the memory cells of the first input/output unit, and Rapn may indicate a resistance distribution of the memory cells of the n-th input/output unit, n being a natural number equal to or greater than 2.

The test device may count the number of fail bits of the memory cells of the memory device 100. For example, when the read operation is performed by using a reference resistance of a relatively small value (e.g., R1), the number of fail bits may be small. As a value (e.g., R31) of the reference resistance becomes greater, the number of fail bits may increase. As the reference resistance value varies, the number of counted fail bits varies like a graph marked by G2.

The test device may sum the graph G1 indicating the number of fail bits measured in the parallel state and the graph G2 indicating the number of fail bits measured in the anti-parallel state. A graph indicated by G3 may be drawn as a sum result. In the graph indicated by G3, a resistance value (i.e., R8) corresponding to the smallest number of fail bits may be an optimal global reference resistance value of the memory device 100. The way to obtain a global reference resistance value depending on the above method may be called coarse trim.

Meanwhile, as illustrated in FIG. 12, in the case of obtaining a global reference resistance value to be applied to all the memory cells of the memory device 100, a read margin RM may range from the upper limit of the parallel state distribution Rpn of the memory cells of the n-th input/output unit to the lower limit of the anti-parallel state distribution Rap1 of the memory cells of the first input/output unit. That is, the read margin RM of the global reference resistance value may be smaller than an original read margin of each input/output unit. Accordingly, to solve the issue that the read margin RM decreases, according to the present disclosure, a value of a local reference resistance to be applied for each input/output unit may be obtained. In addition, to reduce test time and costs, a test operation for obtaining a value of a local reference resistance may be performed in a specific resistance section.

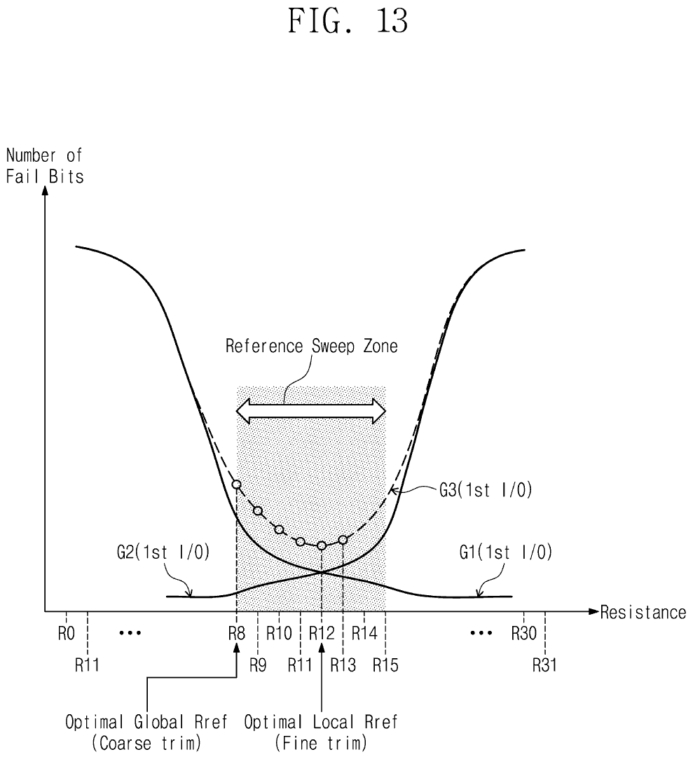

FIG. 13 is a graph for showing how to determine a value of a local reference resistance for distinguishing program states of memory cells according to example embodiments.

In an embodiment, a value of an optimal reference resistance (i.e., a local reference resistance) for each of input/output units constituting the memory device 100 (refer to FIG. 8) may be determined. For example, a value of the reference resistance Rref_C1_I/O1 of the first input/output unit 1st I/O and a value of the reference resistance Rref_C1_I/O2 of the second input/output unit 2nd I/O may be individually determined. In an embodiment, it is assumed that the value of the local reference resistance of the first input/output unit 1st I/O of FIG. 8 is determined. Compared to the coarse trim, an operation of obtaining a value of a local reference resistance to be applied to memory cells of an input/output unit may be called fine trim.

Referring to FIG. 13, a graph indicated by G1 may indicate the number of fail bits of the memory cells of the first input/output unit 1st I/O, which are programmed to the parallel state, for each resistance value. A graph indicated by G2 may indicate the number of fail bits of the memory cells of the first input/output unit 1st I/O, which are programmed to the anti-parallel state, for each resistance value. A graph indicated by G3 may indicate a sum of the graph indicated by G1 and the graph indicated by G2.

At the test step, a reference sweep zone including a global reference resistance value may be set. The reference sweep zone may mean a zone which is a part of a range of resistance values used to count fail bits and includes a global reference resistance value. In an embodiment, the lower limit of the reference sweep zone may be set to a value R8 of the global reference resistance. In this case, the upper limit of the reference sweep zone may be appropriately set in consideration of a resistance distribution of memory cells of an input/output unit (e.g., may be set to R15). In another embodiment, the upper limit of the reference sweep zone may be set to the value R8 of the global reference resistance, and the lower limit thereof may be set in consideration of a resistance distribution of memory cells of an input/output unit. In another embodiment, the global reference resistance value R8 may be set to correspond to a value between the upper limit and the lower limit of the reference sweep zone. However, the reference sweep zone may be set in various methods such that the global reference resistance value is included in the reference sweep zone and is not limited to the above examples.

At the test step, fail bit counting may be performed by using at least some of the resistance values R8 to R15 in the reference sweep zone. In an embodiment, a start point of the fine trim may be the global reference resistance value R8. Afterwards, the fail bit counting may be performed by using the remaining resistance values in the reference sweep zone. As a counting value, a resistance value (i.e., R12) corresponding to the smallest counting value may be selected as the optimal local reference resistance value of the first input/output unit 1st I/O. For example, depending on an input/output unit, the local reference resistance value may be the same as, smaller than or greater than the global reference resistance value.

In an embodiment, the fail bit counting may be performed in a linear search method. For example, fail bits may be counted while changing the resistance value from R8 to R15. However, when the trend that the number of fail bits increases is detected during the fail bit counting (e.g., during the fail bit counting using the resistance value R13), the test device may stop the fail bit counting and may determine a resistance value (i.e., R12) corresponding to the smallest counting value (i.e., the smallest number of fail bits) from among counting values measured up to now as an optimal local reference resistance value.

In an embodiment, the fail bit counting may be performed in a binary search method. However, the method of searching for the smallest counting value is not limited thereto, and various methods may be used.

In an embodiment, the test device may determine an optimal write voltage (or read voltage) value for the first input/output unit 1st I/O of the memory device 100, based on the optimal local reference resistance value (i.e., R12). The value of the read voltage may be drawn from the tendency of the size of the MRAM cell measured in advance, a reference resistance value according to the size of the MRAM cell, and a value of the write voltage according to the reference resistance value.

In an embodiment, the case where the optimal local reference resistance value is relatively small (e.g., a value close to R8) may mean that the size of the MRAM cell of the first input/output unit 1st I/O is relatively large, which may mean that a write voltage of a relatively great value is required. In contrast, the case where the optimal local reference resistance value is relatively great (e.g., a value close to R15) may mean that the size of the MRAM cell of the first input/output unit 1st I/O is relatively small, which may mean that a write voltage of a relatively small value is required.

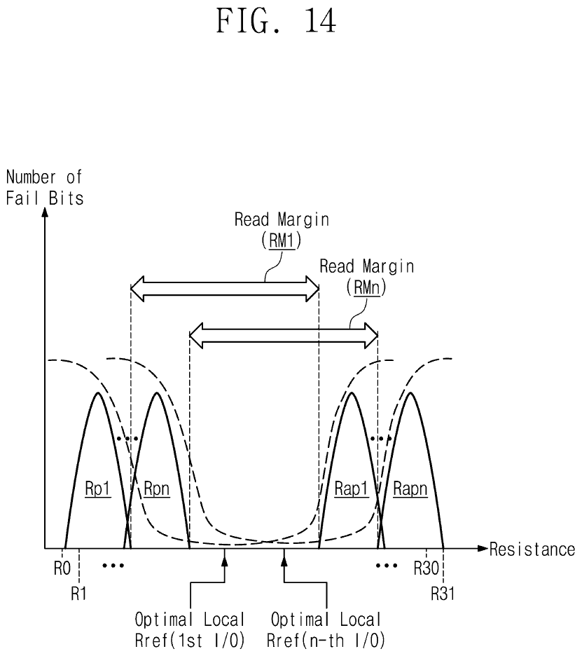

FIG. 14 is a graph conceptually illustrating how a read margin increases when a local reference resistance value is obtained for each input/output unit, according to an embodiment of the present disclosure.

A read margin RM1 of the first input/output unit 1st I/O may range from the upper limit of the parallel state distribution Rp1 of the memory cells of the first input/output unit 1st I/O and the lower limit of the anti-parallel state distribution Rap1 of the memory cells of the first input/output unit 1st I/O. Also, a read margin RMn of the n-th input/output unit n-th I/O may range from the upper limit of the parallel state distribution Rpn of the memory cells of the n-th input/output unit n-th I/O and the lower limit of the anti-parallel state distribution Rapn of the memory cells of the n-th input/output unit n-th I/O. For example, compared to the read margin RM of the global reference resistance illustrated in FIG. 12, it may be understood that each of the read margins RM1 and RMn of local reference resistances considerably increases.

In addition, according to an embodiment of the present disclosure, because each local reference resistance value is obtained by not performing the fail bit counting for all the resistance values but performing the fail bit counting in the reference sweep zone, the test time and costs may be reduced.

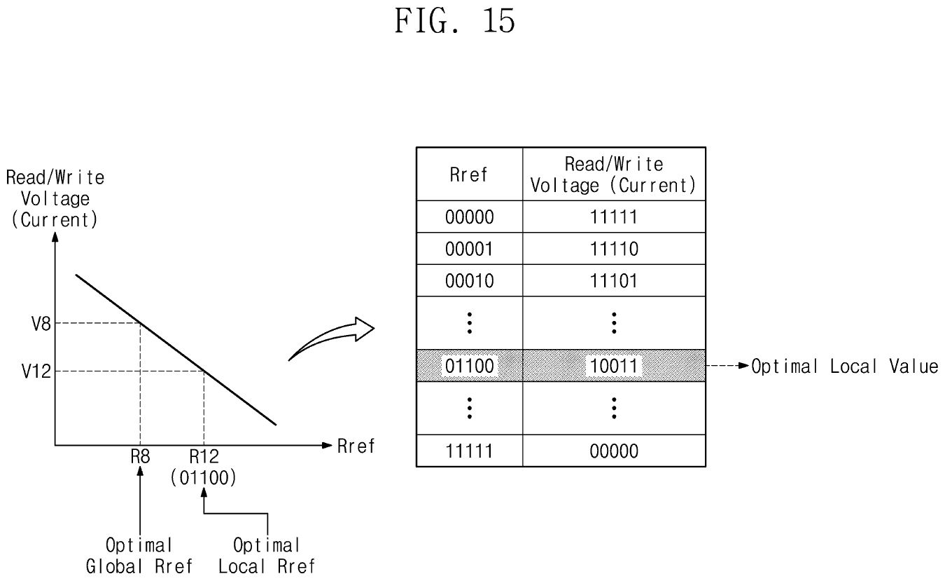

FIG. 15 conceptually illustrates a relationship between a value of a reference resistance and a value of a read voltage or a write voltage corresponding thereto according to example embodiments.

In an embodiment, a local reference resistance value of an input/output unit of a memory device may be inversely proportional to a value of a read/write voltage (or current) of the memory device, which corresponds to the local reference resistance value. However, the reference resistance value of the input/output unit of the memory device may not be accurately inversely proportional to an optimal read/write voltage value corresponding thereto. It should be understood that the corresponding read/write voltage value decreases as the reference resistance value increases.

In a graph of FIG. 15, a relatively small optimal global reference resistance value R8 represents that the memory device is composed of relatively large memory cells. However, as the fine trim result, there may be determined that an optimal local reference resistance value of the first input/output unit 1st I/O is R12, which represents that the size of the memory cells of the first input/output unit 1st I/O are generally smaller than the overall size of the memory cells of the memory device. Accordingly, the value of the write voltage to be globally applied to the memory device may be V8; however, according to the fine trim result of the present disclosure, there may be confirmed that a value of the write voltage to be applied to the first input/output unit 1st I/O of the memory device is V12 less than V8. The above description may be identically applied to the read voltage.

In an embodiment, each of a value of the reference resistance and a value of the read/write voltage (or current) may be expressed by 5 bits, but the present invention is not limited thereto. In the case where the reference resistance value is expressed by 5 bits, the fail bit counting operation described with reference to FIG. 12 may be performed as much as 32 times or less for each of the parallel state and the anti-parallel state. For example, the read/write voltage (or current) may be variable between a first value corresponding to “11111” and a second value corresponding to “00000”.

In an embodiment, the local reference resistance value R12 and the optimal read/write voltage (or current) value obtained through the table of FIG. 15 may be stored in the OTP memory. The local reference resistance value R12 may be selected as a reference resistance value of the first input/output unit 1st I/O of FIG. 8 and may be used in the read operation.

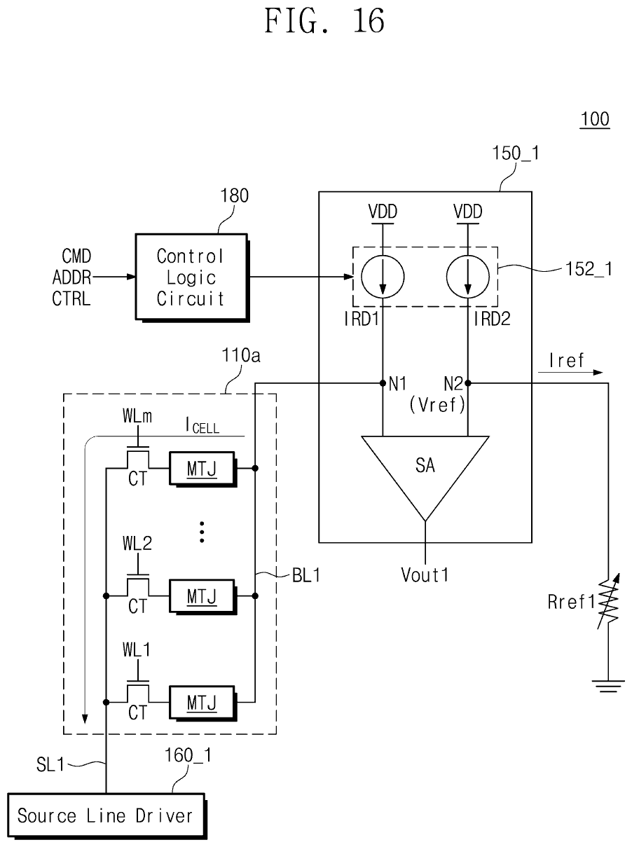

FIG. 16 illustrates a configuration associated with a read operation on the memory cell array 110 of FIG. 8 according to example embodiments.

In an embodiment, the memory device 100 may include a memory cell array composed of the first region 110a, the sensing circuit 150_1, the source line driver 160_1, and the control logic circuit 180. For example, the memory cell array may not include a dummy region, and the reference resistance Rref1 may be connected between the second node N2 and the ground electrode. A configuration and an operation of the memory cell array 110 of FIG. 16 are mostly the same as those of the memory cell array of FIG. 8 except for the above difference, and thus, additional description will be omitted to avoid redundancy.

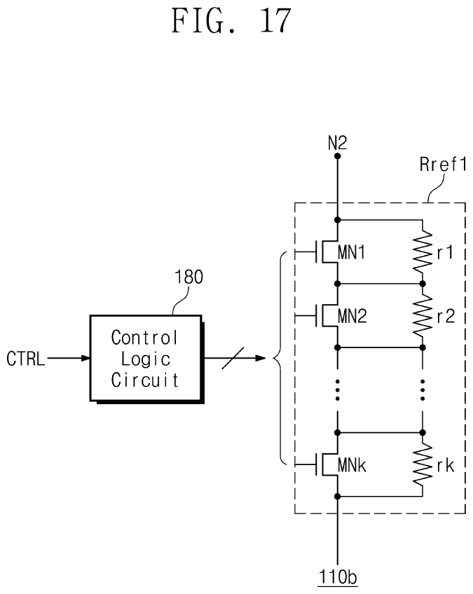

FIG. 17 illustrates a configuration of the reference resistance Rref1 of FIG. 11 according to example embodiments.

The reference resistance Rref1 may be configured such that a resistance value thereof is changed under control of the control logic circuit 180. For example, the control logic circuit 180 may control the reference resistance Rref1, based on the control signal CTRL including information about the optimal local reference resistance value determined in FIG. 13. For example, the information about the optimal local reference resistance value may be read from the OTP memory of the memory device 100.

In an embodiment, the reference resistance Rref1 may include a plurality of transistors MN1 to MNk and a plurality of resistance elements r1 to rk, k being a natural number equal to or greater than 2. For example, the plurality of transistors MN1 to MNk may be respectively connected to the plurality of resistance elements r1 to rk in parallel. The plurality of transistors MN1 to MNk may be individually turned on or turned off under control of the control logic circuit 180. When a transistor of the plurality of transistors MN1 to MNk is turned on, a current may flow from the second node N2 to the ground electrode through the reference resistance Rref1 including the turned-on transistor and the second region 110b; in this case, it may be regarded that no current flows through a resistance element connected between opposite ends of the turned-on transistor. For example, when the transistor MN1 is turned off and the remaining transistors MN2 to MNk are turned on, a path of a current flowing from the second node N2 to the second region 110b may be “r1-MN2-, . . . , and-MNk”, and a value of the reference resistance Rref1 may be “r1”.

However, the configuration of the reference resistance Rref1 is not limited to the example illustrated in FIG. 17, and various configurations in which a resistance value is changed under control the control logic circuit 180 may be adopted.

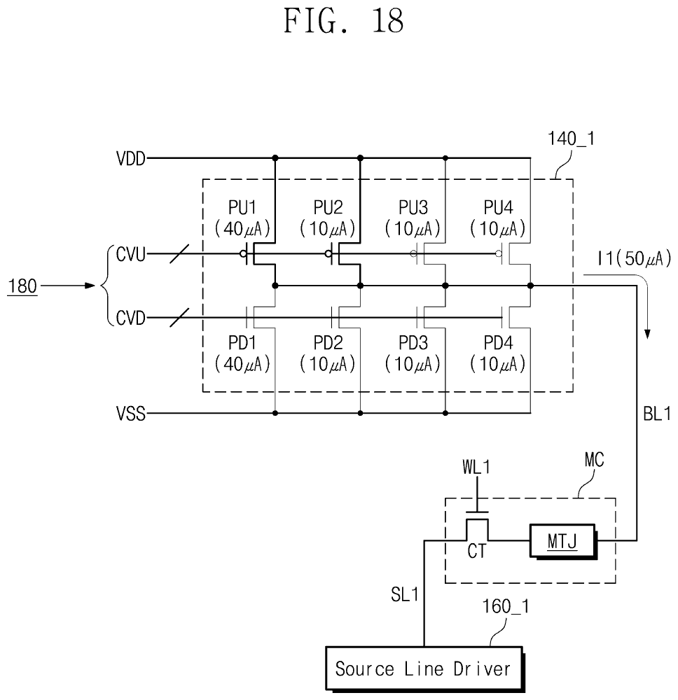

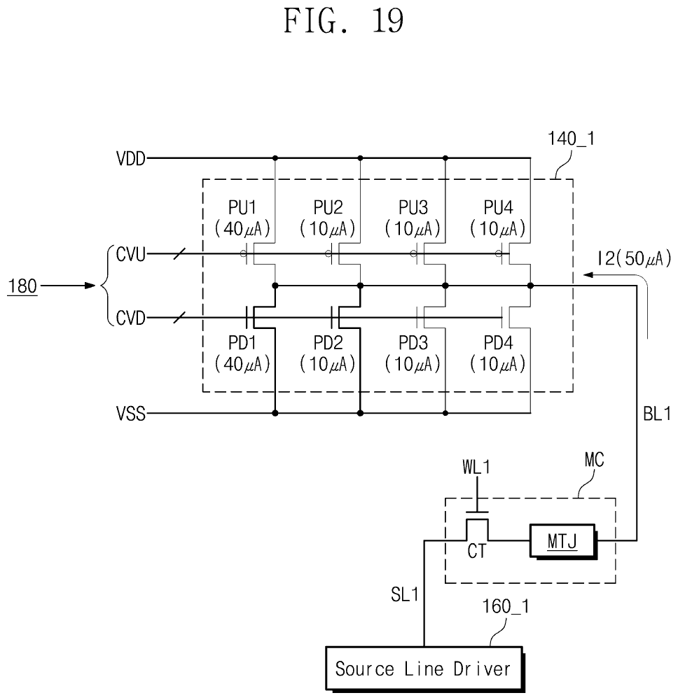

FIGS. 18 and 19 are circuit diagrams associated with a pre-program operation or a program operation of the write driver 140_1 of FIG. 9 according to example embodiments.

Referring to FIGS. 18 and 19, the write driver 140_1 may include transistors PU1 to PU4 and transistors PD1 to PD4. For example, each of the transistors PU1 and PD1 may have a channel width for driving a current of 40 μA, and each of the transistors PU2 to PU4 and PD2 to PD4 may have a channel width for driving a current of 10 μA.

In an embodiment, FIG. 18 may be associated with the case where the write driver 140_1 pulls up a voltage of the first bit line BL1 to a first power supply voltage VDD. In the embodiment of FIG. 18, the write driver 140_1 may receive a first code value CVU of “0011” and a second code value CVD of “0000” from the control logic circuit 180 (refer to FIG. 9).

Referring to FIG. 18, the transistors PD1 to PD4 may be turned off in response to the second code value CVD of “0000”. The transistors PU1 and PU2 may be turned on in response to bits of “00” of the first code value CVU, and the transistors PU3 and PU4 may be turned off in response to bits “11” of the first code value CVU. Accordingly, a write current I1 of 50 μA may be driven through the turned-on transistors PU1 and PU2.

In an embodiment, FIG. 19 may be associated with the case where the write driver 140_1 pulls down a voltage of the first bit line BL1 to a second power supply voltage VSS, for example, a ground voltage. In the embodiment of FIG. 19, the write driver 140_1 may be provided with the first code value CVU of “1111” and the second code value CVD of “1100” from the control logic circuit 180.

Referring to FIG. 19, the transistors PU1 to PU4 may be turned off in response to the first code value CVU of “1111”. The transistors PD1 and PD2 may be turned on in response to bits of “11” of the second code value CVD, and the transistors PD3 and PD4 may be turned off in response to bits “00” of the second code value CVD. Accordingly, a write current 12 of 50 μA may be driven through the turned-on transistors PD1 and PD2.

In an embodiment, the embodiment of FIG. 18 may be associated with the case of storing data of logic “0” in the memory cell MC, and the embodiment of FIG. 19 may be associated with the case of storing data of logic “1” in the memory cell MC. For example, to provide the code values CVU and CVD to the transistors PU1 to PU4 and PU1 to PU4 constituting the write driver 140_1, the control logic circuit 180 may include components such as a switch and a multiplexer.

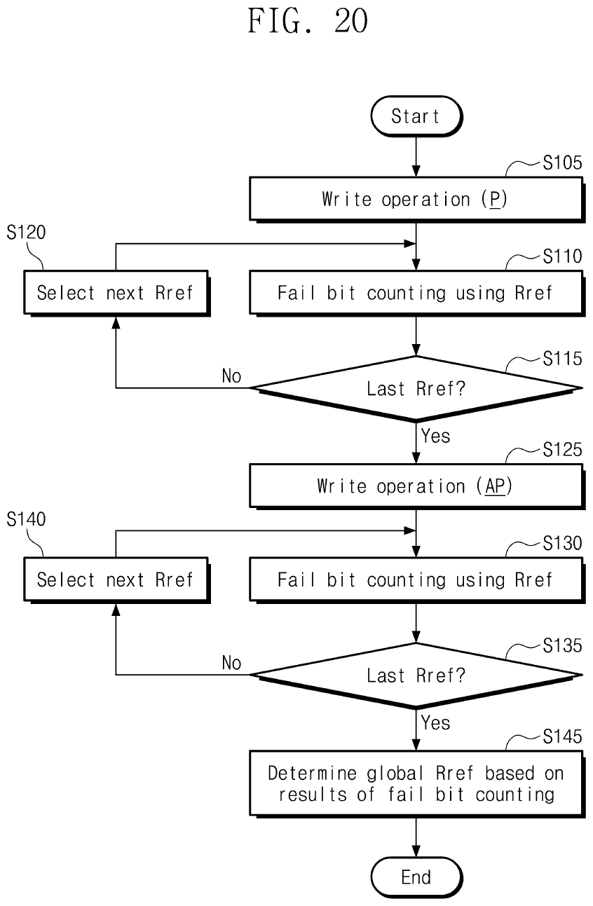

FIG. 20 is a flowchart illustrating a test method of a memory device according to an embodiment of the present disclosure.

In operation S105, the pre-program operation on memory cells of a memory device may be performed. For example, the test device may program the memory cells constituting the memory device to a parallel state (e.g., Rp1).

In operation S110, fail bit counting for the memory cells of the memory device may be performed. In an embodiment, the test device may count the number of fail bits of the memory cells by varying values of reference resistances (e.g., Rref1 and Rref2 of FIG. 8). For example, the first reference resistance Rref1 may be used to count fail bits of the memory cells of the first input/output unit 1st I/O (refer to FIG. 8), and the second reference resistance Rref2 may be used to count fail bits of the memory cells of the second input/output unit 2nd I/O (refer to FIG. 8).

The test device may count the fail bit counting for the memory cells while varying values of the reference resistances Rref1 and Rref2 (i.e., may repeatedly perform operation S110, operation S115, and operation S120). For example, the test device may control the reference resistances Rref1 and Rref2 (refer to FIG. 8) such that the reference resistances Rref1 and Rref2 have next resistance values, and the test device may perform the fail bit counting by using the changed reference resistance values. When the fail bit counting using all the predetermined reference resistance values are completed, the fail bit counting operation associated with the parallel state may end.

In operation S125, the pre-program operation on the memory cells of the memory device may be performed. For example, the test device may program the memory cells constituting the memory device to an anti-parallel state (e.g., Rap1).

In operation S130, fail bit counting for the memory cells of the memory device may be performed. In an embodiment, the test device may count the number of fail bits of memory cells while varying values of the reference resistances Rref1 and Rref2.

Afterwards, the test device may count the number of fail bits of the memory cells while varying values of the reference resistances Rref1 and Rref2 (i.e., may repeatedly perform operation S130, operation S135, and operation S140); when the fail bit counting using all the predetermined reference resistance values is completed, the fail bit counting operation on the anti-parallel state may end.

In operation S145, a global reference resistance value may be determined based on the fail bit counting results. For example, the test device may sum the number of fail bits in the parallel state counted for each reference resistance value and the number of fail bits in the anti-parallel state counted for each reference resistance value and may select a resistance value with the smallest summation result as the global reference resistance value.

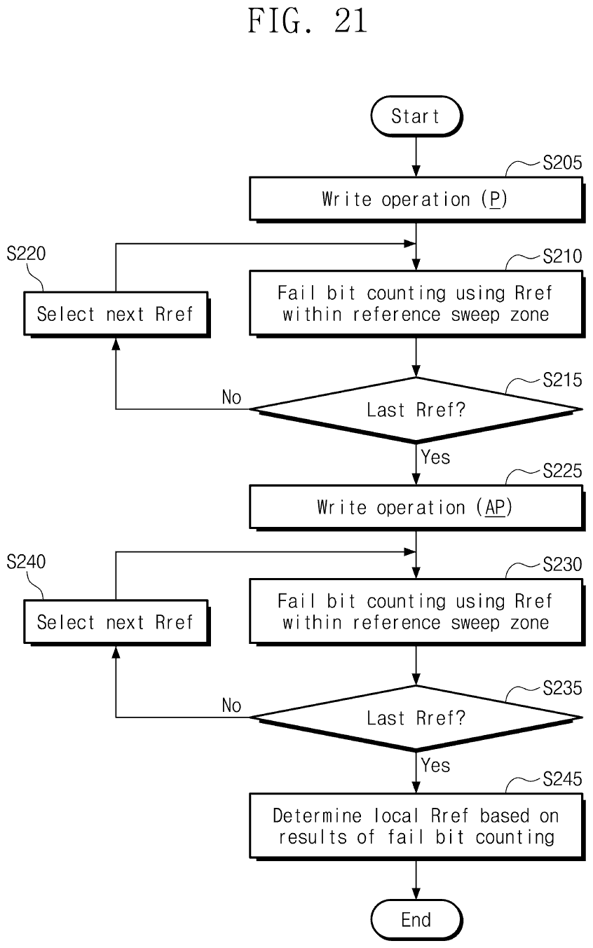

FIG. 21 is a flowchart illustrating a test method of a memory device according to an embodiment of the present disclosure.

In operation S205, the pre-program operation on the first input/output unit 1st I/O (refer to FIG. 8) of the memory device may be performed. For example, the test device may program the memory cells of the first input/output unit 1st I/O (refer to FIG. 8) to form a resistance distribution (e.g., Rp1) of the parallel state of FIG. 10.

In operation S210, fail bit counting for the memory cells of the first input/output unit 1 st I/O (refer to FIG. 8) may be performed within a range of the reference sweep zone. As described with reference to FIG. 19, the reference sweep zone may mean a zone which is a part of a range of resistance values used to count fail bits and includes a global reference resistance value. The test device may count the number of fail bits of the memory cells of the first input/output unit 1st I/O (refer to FIG. 8) while varying a value of the first reference resistance Rref1 (refer to FIG. 8).

Afterwards, the test device may count the number of fail bits of the memory cells of the first input/output unit 1st I/O (refer to FIG. 8) while varying a value of the first reference resistance Rref1 (i.e., may repeatedly perform operation S210, operation S215, and operation S220). For example, the test device may control the reference resistance Rref1 such that the reference resistance Rref1 has a next resistance value, and the test device may perform the fail bit counting by using the changed reference resistance value. When the fail bit counting using reference resistance values in the reference sweep zone is completed, the fail bit counting operation associated with the parallel state may end.

In operation S225, the pre-program operation on the memory cells of first input/output unit 1st I/O (refer to FIG. 8) may be performed within the range of the reference sweep zone. For example, the test device may program the memory cells of the first input/output unit 1st I/O (refer to FIG. 8) to form a resistance distribution (e.g., Rap1) of the anti-parallel state of FIG. 10.

In operation S230, fail bit counting for the memory cells of the first input/output unit 1st I/O (refer to FIG. 8) may be performed within the range of the reference sweep zone. The test device may count the number of fail bits of the memory cells of the first input/output unit 1st I/O (refer to FIG. 8) while varying a value of the first reference resistance Rref1.

Afterwards, the test device may count the number of fail bits of the memory cells of the first input/output unit 1st I/O (refer to FIG. 8) while varying a value of the reference resistance Rref1 (i.e., may repeatedly perform operation S230, operation S235, and operation S240); when the fail bit counting using reference resistance values in the reference sweep zone is completed, the fail bit counting operation on the anti-parallel state may end.

In operation S245, a value of a local reference resistance for the first input/output unit 1st I/O (refer to FIG. 8) may be determined based on fail bit counting results. For example, the test device may sum the number of fail bits in the parallel state counted for each reference resistance value in the reference sweep zone and the number of fail bits in the anti-parallel state counted for each reference resistance value in the reference sweep zone and may select a resistance value with the smallest summation result as the local reference resistance value for the first input/output unit 1st I/O.

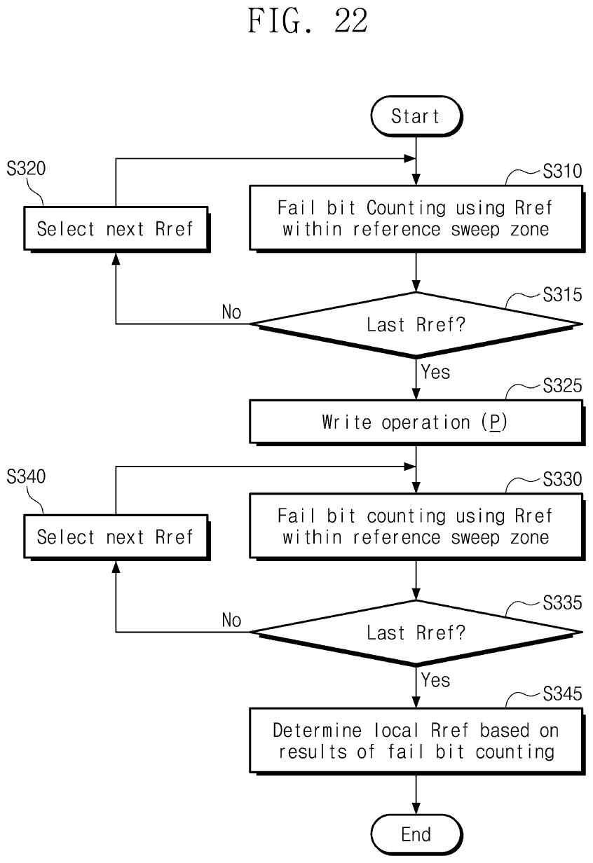

FIG. 22 is a flowchart illustrating a test method of a memory device according to an embodiment of the present disclosure.

FIG. 22 is another embodiment of a method of obtaining a local reference resistance value, which is described with reference to FIG. 21. Because the operation of obtaining the local reference resistance value, which is described with reference to FIG. 22, is performed after the operation of obtaining the global reference resistance value, which is described with reference to FIG. 20, immediately after the global reference resistance value is obtained, the memory cells may be in the anti-parallel (AP) state. Accordingly, it is possible to omit the operation of reprogramming the memory cells to the anti-parallel (AP) state unnecessarily.

In detail, because the memory cells are in the anti-parallel (AP) state immediately after the global reference resistance value is obtained, in operation S310, fail bit counting for the memory cells of the first input/output unit 1st I/O (refer to FIG. 8) may be performed within the range of the reference sweep zone. Afterwards, the fail bit counting may be repeated while varying a reference resistance value (operation S315 and operation S320 may be repeated).

When the fail bit counting for the memory cells of the first input/output unit 1st I/O (refer to FIG. 8), which are programmed to the anti-parallel (AP) state, is completed, the memory cells of the first input/output unit 1st I/O (refer to FIG. 8) may be programmed to the parallel (P) state (S325). Afterwards, the fail bit counting may be repeated while varying a reference resistance value (operation S335 and operation S340 may be repeated). Finally, in operation S345, the local reference resistance value of the first input/output unit 1st I/O (refer to FIG. 8) may be obtained based on the number of fail bits in the parallel state counted for each reference resistance value in the reference sweep zone and the number of fail bits in the anti-parallel state counted for each reference resistance value in the reference sweep zone.

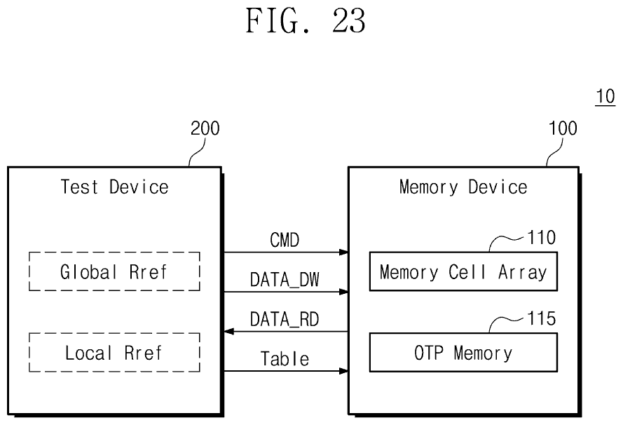

FIG. 23 is a block diagram associated with testing a memory device, according to an embodiment of the present disclosure.

Referring to FIG. 23, a test system 10 may include the memory device 100 and a test device 200.

The memory device 100 includes the memory cell array 110. The memory device 100 may be an implementation example of the memory device 100 described through to FIGS. 1 to 22. The memory cell array 110 may include a first region (e.g., 110a of FIG. 8) and a second region (e.g., 110b of FIG. 8). The first region 110a may be a region where data intended by the user are stored, and the second region 110b may be a dummy region.

The memory device 100 may include an OTP memory 115. The OTP memory 115 may store the global reference resistance value and the local reference resistance values described with reference to FIGS. 1 to 22. The global reference resistance value and the local reference resistance values may be loaded and used in the read operation of the memory device 100.

A test device 200 may perform various test operations on the memory device 100. To this end, the test device 200 may transmit the command CMD to the memory device 100.

In an embodiment, the command CMD may include a command for programming the first region 110a of the memory cell array 110 to a specific program state (e.g., the parallel state or the anti-parallel state). The test device 200 may transmit dummy write data DATA_DW for programming the first region 110a to the parallel state or the anti-parallel state, together with transmitting the command CMD.

In an embodiment, the command CMD may be used to perform the read operation for counting the number of fail bits for each reference resistance value in association with the specific program state (i.e., the parallel state or the anti-parallel state). Read data DATA_RD may be received from the memory device 100 as a read result.

In an embodiment, the test device 200 may count the number of fail bits for each reference resistance value based on the read data DATA_RD received from the memory device 100 and may determine an optimal global reference resistance value and an optimal local reference resistance value based on counting results.

A memory device of the present disclosure may provide an optimal reference resistance value which is used in the read operation. In detail, as well as a global reference resistance value capable of being globally applied to all the memory cells of the memory device, an optimal local reference resistance value capable of being applied for each input/output unit may also be provided. Accordingly, a read error may be markedly reduced.

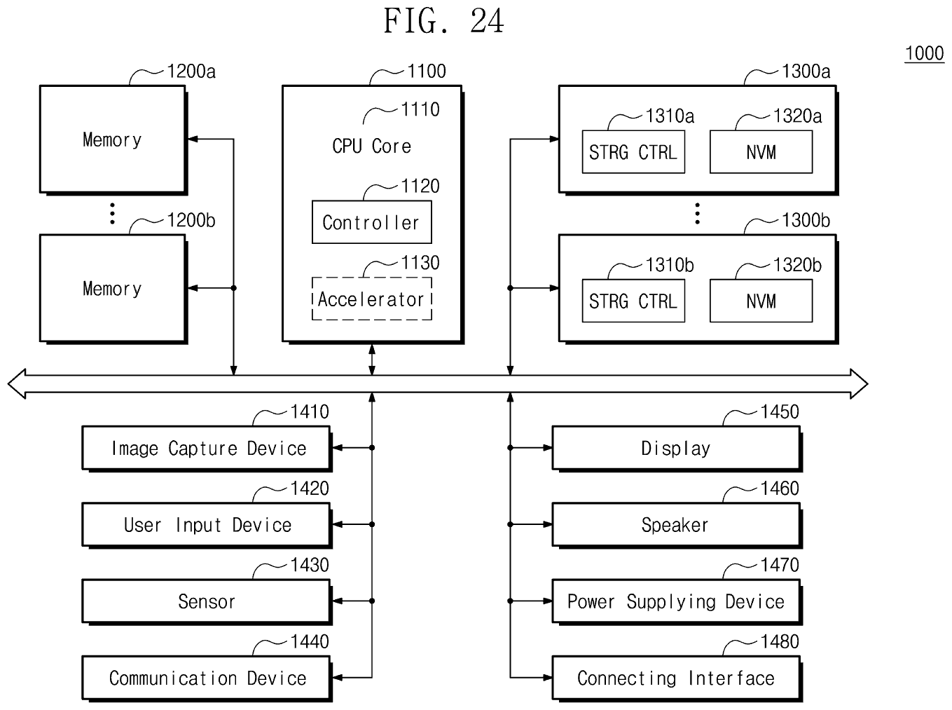

FIG. 24 is a diagram of a system 1000 to which a memory device is applied, according to an embodiment.

The system 1000 may basically be a mobile system, such as a portable communication terminal (e.g., a mobile phone), a smartphone, a tablet personal computer (PC), a wearable device, a healthcare device, or an Internet of things (IOT) device. However, the system 1000 is not necessarily limited to the mobile system and may be a PC, a laptop computer, a server, a media player, or an automotive device (e.g., a navigation device).

A main processor 1100 may control all operations of the system 1000, more specifically, operations of other components included in the system 1000. The main processor 1100 may be implemented as a general-purpose processor, a dedicated processor, or an application processor.

The main processor 1100 may include at least one CPU core 1110 and further include a controller 1120 configured to control memories 1200a and 1200b and/or storage devices 1300a and 1300b. In some embodiments, the main processor 1100 may further include an accelerator 1130, which is a dedicated circuit for a high-speed data operation, such as an artificial intelligence (AI) data operation. The accelerator 1130 may include a graphics processing unit (GPU), a neural processing unit (NPU) and/or a data processing unit (DPU) and be implemented as a chip that is physically separate from the other components of the main processor 1100.

The memories 1200a and 1200b may be used as main memory devices of the system 1000. Although each of the memories 1200a and 1200b may include a volatile memory, such as static random access memory (SRAM) and/or dynamic RAM (DRAM), each of the memories 1200a and 1200b may include non-volatile memory, such as a flash memory, phase-change RAM (PRAM) and/or resistive RAM (RRAM). The memories 1200a and 1200b may be implemented in the same package as the main processor 1100.

The storage devices 1300a and 1300b may serve as non-volatile storage devices configured to store data regardless of whether power is supplied thereto, and have larger storage capacity than the memories 1200a and 1200b. The storage devices 1300a and 1300b may respectively include storage controllers (STRG CTRL) 1310a and 1310b and NVMs (Non-Volatile Memories) 1320a and 1320b configured to store data via the control of the storage controllers 1310a and 1310b. Although the NVMs 1320a and 1320b may include flash memories having a two-dimensional (2D) structure or a three-dimensional (3D) V-NAND structure, the NVMs 1320a and 1320b may include other types of NVMs, such as PRAM and/or RRAM.

The storage devices 1300a and 1300b may be physically separated from the main processor 1100 and included in the system 1000 or implemented in the same package as the main processor 1100. In addition, the storage devices 1300a and 1300b may have types of solid-state devices (SSDs) or memory cards and be removably combined with other components of the system 1000 through an interface, such as a connecting interface 1480 that will be described below. The storage devices 1300a and 1300b may be devices to which a standard protocol, such as a universal flash storage (UFS), an embedded multi-media card (eMMC), or a non-volatile memory express (NVMe), is applied, without being limited thereto. An image capturing device 1410 may capture still images or moving images. The image capturing device 1410 may include a camera, a camcorder, and/or a webcam.

A user input device 1420 may receive various types of data input by a user of the system 1000 and include a touch pad, a keypad, a keyboard, a mouse, and/or a microphone.

The user input device 1420 may receive various types of data input by a user of the system 1000 and include a touch pad, a keypad, a keyboard, a mouse, and/or a microphone.

A sensor 1430 may detect various types of physical quantities, which may be obtained from the outside of the system 1000, and convert the detected physical quantities into electric signals. The sensor 1430 may include a temperature sensor, a pressure sensor, an illuminance sensor, a position sensor, an acceleration sensor, a biosensor, and/or a gyroscope sensor.

A communication device 1440 may transmit and receive signals between other devices outside the system 1000 according to various communication protocols. The communication device 1440 may include an antenna, a transceiver, and/or a modem.

A display 1450 and a speaker 1460 may serve as output devices configured to respectively output visual information and auditory information to the user of the system 1000.

A power supplying device 1470 may appropriately convert power supplied from a battery (not shown) embedded in the system 1000 and/or an external power source, and supply the converted power to each of components of the system 1000.

The connecting interface 1480 may provide connection between the system 1000 and an external device, which is connected to the system 1000 and capable of transmitting and receiving data to and from the system 1000. The connecting interface 1480 may be implemented by using various interface schemes, such as advanced technology attachment (ATA), serial ATA (SATA), external SATA (e-SATA), small computer system interface (SCSI), serial attached SCSI (SAS), peripheral component interconnection (PCI), PCI express (PCIe), NVMe, IEEE 1394, a universal serial bus (USB) interface, a secure digital (SD) card interface, a multi-media card (MMC) interface, an eMMC interface, a UFS interface, an embedded UFS (eUFS) interface, and a compact flash (CF) card interface.

Embodiments of the present disclosure provide a method of determining an optimal reference resistance value for determining a program state of a memory cell through the minimum number of test times. Accordingly, test time and costs may be reduced. In particular, according to embodiments of the present disclosure, not only a reference resistance value to be globally applied to the memory device but also a reference resistance value to be locally applied to a specific input/output unit of the memory device are provided through the minimum number of test times.

While the present invention has been described with reference to embodiments thereof, it will be apparent to those of ordinary skill in the art that various changes and modifications may be made thereto without departing from the spirit and scope of the present invention as set forth in the following claims.

What is claimed is:

1. A memory device comprising:
a memory cell array including a first input/output unit and a second input/output unit, each of the first input/output unit and the second input/output unit including a first region including a plurality of memory cells and a second region including dummy memory cells;
a first sensing circuit configured to determine data stored in the memory cells of the first input/output unit based on a first reference resistance;
a second sensing circuit configured to determine data stored in the memory cells of the second input/output unit based on a second reference resistance; and
a control logic circuit configured to control a value of the first reference resistance and a value of the second reference resistance,
wherein the value of the first reference resistance and the value of the second reference resistance are different from each other.

2. The memory device of claim 1, wherein the first sensing circuit includes:
a first current source configured to generate a first read current;
a second current source configured to generate a second read current; and
a first sense amplifier including a first node connected to a first bit line connected to memory cells of the first input/output unit and a second node connected to a first reference bit line connected to dummy memory cells of the first input/output unit, and the first sense amplifier configured to amplify a difference between a voltage of the first node and a voltage of the second node, and
wherein the first read current is applied to the first bit line and the second read current is applied to the first reference bit line.

3. The memory device of claim 2, wherein the second sensing circuit includes:
a third current source configured to generate a third read current;
a fourth current source configured to generate a fourth read current; and
a second sense amplifier including a third node connected to a second bit line connected to memory cells of the second input/output unit and a fourth node connected to a second reference bit line connected to dummy memory cells of the second input/output unit, and the second sense amplifier configured to amplify a difference between a voltage of the third node and a voltage of the fourth node, and
wherein the third read current is applied to the second bit line and the fourth read current is applied to the second reference bit line.

4. The memory device of claim 1, further comprising:
a first write driver configured to perform a program operation on memory cells of the first region of the first input/output unit under control of the control logic circuit; and
a second write driver configured to perform a program operation on memory cells of the first region of the second input/output unit under control of the control logic circuit.

5. The memory device of claim 4, further comprising:
a first source line driver configured to perform the program operation on the memory cells of the first region of the first input/output unit under control of the control logic circuit; and
a second source line driver configured to perform the program operation on the memory cells of the first region of the second input/output unit under control of the control logic circuit.

6. The memory device of claim 1, wherein each of the plurality of memory cells includes:
a cell transistor including a first end connected to a source line and a gate electrode connected to a word line; and
a magnetic tunneling junction element including a first end connected to a second end of the cell transistor and a second end connected to a bit line.

7. The memory device of claim 1, wherein the value of the first reference resistance is obtained based on a first counting value and a second counting value,
wherein the first counting value is obtained by performing a fail bit counting operation on memory cells of the memory cell array based on a plurality of resistances having different values from each other, and
wherein the second counting value is obtained by performing a fail bit counting operation on memory cells of the first input/output unit based on a first set of resistances among the plurality of resistances.

8. The memory device of claim 7, wherein the fail bit counting operation on the memory cells of the first input/output unit based on the first set of resistances is performed in a linear search method or a binary search method.

9. The memory device of claim 1, wherein the first reference resistance includes a plurality of first transistors and a plurality of first resistance elements respectively connected to the plurality of first transistors in parallel, and
wherein the second reference resistance includes a plurality of second transistors and a plurality of second resistance elements respectively connected to the plurality of second transistors in parallel.

10. The memory device of claim 9, further comprising:
a one-time programmable (OTP) memory configured to store the value of the first reference resistance and the value of the second reference resistance.

11. A method of operating a memory device which includes a memory cell array including a plurality of input/output units and a plurality of memory cells, the method comprising:
programming the plurality of memory cells of the memory cell array to a first state;
first counting fail bits of the memory cells programmed to the first state by using a plurality of resistances having different values from each other and outputting first counting results based on the first counting of fail bits;
programming the plurality of memory cells of the memory cell array to a second state;
second counting fail bits of the memory cells programmed to the second state by using the plurality of resistances and outputting second counting results based on the second counting of fail bits;
selecting a value of a global reference resistance among the plurality of resistances, based on the first counting results and the second counting results;
programming memory cells of a first input/output unit among the plurality of input/output units to the first state;
third counting fail bits of the memory cells of the first input/output unit programmed to the first state by using a first set of resistances among the plurality of resistances and outputting third counting results based on the third counting of fail bits;
programming the memory cells of the first input/output unit to the second state;
fourth counting fail bits of the memory cells of the first input/output unit programmed to the second state by using the first set of resistances and outputting fourth counting results based on the fourth counting of fail bits; and
selecting a value of a local reference resistance among the first set of resistances, based on the third counting results and the fourth counting results.

12. The method of claim 11, wherein the selecting of the value of the global reference resistance includes:
selecting, as the value of the global reference resistance, a value of a resistance corresponding to a smallest summation result among results of summing the first counting results and the second counting results for each of the plurality of resistances.

13. The method of claim 11, wherein the selecting of the value of the local reference resistance includes:
selecting, as the value of the local reference resistance, a value of a resistance corresponding to a smallest summation result among results of summing the third counting results and the fourth counting results for each of the first set of resistances.

14. The method of claim 13, further comprising:
storing the selected value of the local reference resistance in the memory device.

15. The method of claim 11, wherein each of the plurality of memory cells includes a magnetic tunnel junction element.

16. A memory device comprising:
a memory cell array including a plurality of first cell strings, a plurality of second cell strings, a first dummy cell string, and a second dummy cell string;
a first sense amplifier including a first input terminal to which first ends of the plurality of first cell strings are connected and a second input terminal to which a first end of the first dummy cell string is connected through a first reference resistance;
a second sense amplifier including a first input terminal to which first ends of the plurality of second cell strings are connected and a second input terminal to which a first end of the second dummy cell string is connected through a second reference resistance;
a first current source circuit configured to provide a first input current to the first sense amplifier; and
a second current source circuit configured to provide a second input current to the second sense amplifier,
wherein a value of the first reference resistance and a value of the second reference resistance are different from each other.

17. The memory device of claim 16, wherein the value of the first reference resistance is obtained based on:
the number of fail bits counted from memory cells of the first cell strings and the second cell strings based on a plurality of resistances having different values from each other, and
the number of fail bits counted from memory cells of the first cell strings based on a first set of resistances among the plurality of resistances.

18. The memory device of claim 16, further comprising:
a first write driver configured to perform a program operation on memory cells of the plurality of first cell strings; and
a second write driver configured to perform a program operation on memory cells of the plurality of second cell strings.

19. The memory device of claim 16, wherein each of memory cells of the plurality of first cell strings and the plurality of second cell strings includes:
a cell transistor including a first end connected to a source line and a gate electrode connected to a word line; and
a magnetic tunneling junction element including a first end connected to a second end of the cell transistor and a second end connected to a bit line.

20. The memory device of claim 16, wherein each of memory cells of the first dummy cell string and the second dummy cell string includes:
a cell transistor including a first end connected to a source line, a second end connected to a bit line, and a gate electrode connected to a word line.
